(19) United States
(12) Patent Application Publication
(10) Pub. No.: US 2019/0212644 A1
(43) Pub. Date: Jul. 11, 2019

(54) PHOTOSENSITIVE COMPOSITION, CURED FILM, PATTERN FORMING METHOD, COLOR FILTER, SOLID-STATE IMAGING ELEMENT, AND IMAGE DISPLAY DEVICE

(71) Applicant: FUJIFILM Corporation, Tokyo (JP)

(72) Inventors: Hiroyuki Morishita, Haibara-gun (JP); Kazuya Oota, Haibara-gun (JP); Yoshinori Taguchi, Haibara-gun (JP); Akiko Yoshii, Haibara-gun (JP)

(73) Assignee: FUJIFILM Corporation, Tokyo (JP)

(21) Appl. No.: 16/356,109

(22) Filed: Mar. 18, 2019

Related U.S. Application Data
(63) Continuation of application No. PCT/JP2017/033365, filed on Sep. 15, 2017.

(30) Foreign Application Priority Data
Sep. 23, 2016 (JP) 2016-185401

(51) Int. Cl. G03F 7/00; G03F 7/031; G03F 7/16; G03F 7/20; G03F 7/32; G02B 5/20

(52) U.S. Cl. CPC G03F 7/001; G03F 7/031; G03F 7/162; G02B 5/206; G03F 7/2004; G03F 7/322; G03F 7/2024; G03F 7/168

(57) ABSTRACT

Provided is a photosensitive composition capable of Ruining a pattern having excellent rectangularity and solvent resistance. Provided are also a cured film, a pattern forming method, a color filter, a solid-state imaging element, and an image display device. This photosensitive composition includes a white or colorless pigment A, an alkali-soluble resin B, a polymerizable compound C having an ethylenically unsaturated double bond, a photopolymerization initiator D1 having a light absorption coefficient of 1.0×10³ mL/gcm or more at a wavelength of 365 nm in methanol, and a photopolymerization initiator D2 having a light absorption coefficient of 1.0×10² mL/gcm or less at a wavelength of 365 nm in methanol and a light absorption coefficient of 1.0×10³ mL/gcm or more at a wavelength of 254 nm, in which the mass ratio of the photopolymerization initiator D1 to the photopolymerization initiator D2 is photopolymerization initiator D1:photopolymerization initiator D2=90:10 to 40:60.

### CROSS-REFERENCE TO RELATED APPLICATIONS

This application is a Continuation of PCT International Application No. PCT/JP2017/033365 filed on Sep. 15, 2017, which claims priority under 35 U.S.C. § 119(a) to Japanese Patent Application No. 2016-185401 filed on Sep. 23, 2016. Each of the above application(s) is hereby expressly incorporated by reference, in its entirety, into the present application.

### BACKGROUND OF THE INVENTION

### 1. Field of the Invention

The present invention relates to a photosensitive composition, a cured film, a pattern forming method, a color filter, a solid-state imaging element, and an image display device.

### 2. Description of the Related Art

For the purpose of improving the resolution of an image sensor, miniaturization of pixels is in progress in conjunction with an expansion of the number of pixels of the image sensor. Meanwhile, the opening becomes small, which has led to decreased sensitivity. Therefore, there are cases where one of colors of a plurality of colors of a color filter is white (transparent) for the purpose of improving the sensitivity.

As a method for forming various colored pixels, a black matrix, and the like in a color filter, a method of forming the colored pixels, a black matrix, and the like using a photosensitive composition is known (see, for example, JP2009-301049A, JP2010-191119A, JP2015-041058A, and JP2010-097210A).

In addition, as a method for forming a white pattern (white pixels) in a color filter, a method of forming the pattern using a photosensitive composition including a white or colorless pigments is known.

On the other hand, as an invention which relates to a photosensitive composition including a white pigment, an invention which relates to a resin composition for a solder resist, containing a base resin having a carboxyl group, an epoxy resin, and a white pigment is described in JP2015-099924A. In addition, a photosensitive composition for forming a bezel, including (A) a white pigment, (B) a binder resin, (C) a polymerizable compound, (D) a photopolymerization initiator, and (D) a photopolymerization initiator, an invention which relates to a photosensitive composition for forming a bezel, including at least one photopolymerization initiator selected from an 0-acyloxime-based photopolymerization initiator, an a-aminoalkylphenone-based photopolymerization initiator, an acylphosphine oxide-based photopolymerization initiator, or a titanocene-based photopolymerization initiator is described in JP2016-027384A.

### SUMMARY OF THE INVENTION

In recent years, light emitting sources of image display devices have been changed to organic electroluminescent sources, or photoelectric conversion films of image sensors have been changed to organic materials. In terms of the characteristics thereof, there is a demand for forming pixels at a low temperature of approximately 100° C. even in the formation of various pixels in a color filter. However, it could be seen that a color filter manufactured by curing at a low temperature tends to have deteriorated solvent resistance.

On the other hand, by increasing the content of a photopolymerization initiator in a photosensitive composition, it is possible to enhance the exposure sensitivity, and enhance the solvent resistance or the like of a pattern thus obtained. However, as the content of the photopolymerization initiator in the photosensitive composition, the pattern formability easily decreases. Therefore, the rectangularity of the pattern is easily deteriorated.

Furthermore, a photosensitive composition including a white or colorless pigment, which is used to form white pixels or the like in a color filter, has high transparency for light used for exposure, such as i-rays. In this regard, in a case where a photosensitive composition layer formed using such a photosensitive composition is exposed through a mask having a predetermined pattern, there has been a tendency that unexposed portions in the periphery of the mask are easily exposed with reflected light or scattered light from a support, and the rectangularity of the pattern is easily deteriorated. Incidentally, there has been a tendency that as the patterns become thinner films, the rectangularity of the pattern is easily deteriorated.

Moreover, the present inventors have studied the photosensitive composition including a white pigment described in JP2015-099924A and JP2016-027384A, it is difficult to satisfy both of the rectangularity and the solvent resistance with the photosensitive compositions described in these patent documents. Further, JP2009-301049A, JP2010-191119A, JP2015-041058A, and JP2010-097210A describe an invention which relates to a photosensitive composition used for forming colored pixels or a black matrix of a color filter, and have neither consideration nor suggestion on a photosensitive composition including a white or colorless pigment.

Therefore, an object of the present invention is to provide a photosensitive composition capable of forming a pattern having excellent rectangularity and solvent resistance. Another object of the present invention is to provide a cured film, a pattern forming method, a color filter, a solid-state imaging element, and an image display device.

The present inventors have conducted extensive studies, and as a result, they have found that the objects can be accomplished by using a photosensitive composition which will be described later, thus leading to completion of the present invention. That is, the present invention is configured to be as follows.

<1>A photosensitive composition comprising:
a white or colorless pigment A;
an alkali-soluble resin B;
a polymerizable compound C having an ethylenically unsaturated double bond;
a photopolymerization initiator D1 having a light absorption coefficient of 1.0×10³ mL/gcm or more at a wavelength of 365 nm in methanol; and
a photopolymerization initiator D2 having a light absorption coefficient of 1.0×10² mL/gcm or less at a wavelength of 365 nm in methanol and a light absorption coefficient of 1.0×10³ mL/gcm or more at a wavelength of 254 nm,
in which the mass ratio of the photopolymerization initiator D1 to the photopolymerization initiator D2 is photopolymerization initiator D1:photopolymerization initiator D2 =90:10 to 40:60.
   <2>The photosensitive composition as described in <1>,
in which the pigment A is contained in an amount of 20% to 70% by mass in the total solid content of the photosensitive composition.
   <3>The photosensitive composition as described in <1>or <2>,
in which the pigment A includes at least one selected from titanium oxide or zirconium oxide.
   <4>The photosensitive composition as described in any one of <1>to <3>,
in which the photopolymerization initiator D1 is an oxime compound.
   <5>The photosensitive composition as described in any one of <1>to <4>,
in which the photopolymerization initiator D2 is a compound represented by Formula (V);

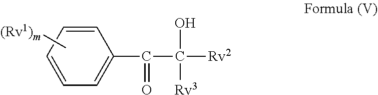

in the formula, Rv¹ represents a substituent, Rv² and Rv³ each independently represent a hydrogen atom or a substituent, Rv² and Rv³ may be bonded to each other to form a ring, and m represents an integer of 0 to 4.

<6>The photosensitive composition as described in any one of <1>to <5>,
in which the photopolymerization initiator D1 and the photopolymerization initiator D2 are contained in a total amount of 4% to 16% by mass in the total solid content of the photosensitive composition.
   <7>The photosensitive composition as described in any one of <1>to <6>,
in which the alkali-soluble resin B has an acid value of 25 to 200 mgKOH/g.
   <8>The photosensitive composition as described in any one of <1>to <7>,
in which the alkali-soluble resin B includes a repeating unit having a hydroxyl group.
   <9>The photosensitive composition as described in any one of <1>to <8>,
in which a hydroxyl number of the alkali-soluble resin B is 30 to 80 mgKOH/g.
   <10>The photosensitive composition as described in any one of <1>to <9>,
which is a composition for forming white pixels in a color filter.
   <11>A cured film formed by curing the photosensitive composition as described in any one of <1>to <10>.
   <12>A pattern forming method comprising:
a step of forming a photosensitive composition layer on a support using the photosensitive composition as described in any one of <1>to <10>;
a step of pattern wise exposing the photosensitive composition layer by irradiation with light at a wavelength of more than 350 nm and 380 nm or less;
a step of developing the photosensitive composition layer after the exposure;
a step of exposing the photosensitive composition layer after the development by irradiation with light at a wavelength of 254 to 350 nm.
   <13>A color filter comprising the cured film as described in <11>.
   <14>A solid-state imaging element comprising the cured film as described in <11>.
   <15>An image display device comprising the cured film as described in <11>.

According to the present invention, it is possible to provide a photosensitive composition capable of forming a pattern having excellent rectangularity and solvent resistance. It is also possible to provide a cured film, a pattern forming method, a color filter, a solid-state imaging element, and an image display device.

### DESCRIPTION OF THE PREFERRED EMBODIMENTS

Hereinafter, the contents of the present invention will be described in detail.

In citations for a group (atomic group) in the present specification, in a case where the group is denoted without specifying whether it is substituted or unsubstituted, the group includes both a group (atomic group) having no substituent and a group (atomic group) having a substituent. For example, an “alkyl group” includes not only an alkyl group having no substituent (unsubstituted alkyl group), but also an alkyl group having a substituent (substituted alkyl group).

In the present specification, “exposure” includes, unless otherwise specified, not only exposure using light but also writing using particle rays such as electron beams and ion beams. In addition, examples of light included in the exposure include actinic rays or radiation such as a bright line spectrum of a mercury lamp, far ultraviolet rays typified by an excimer laser, extreme ultraviolet rays (EUV light), X-rays, electron beams, or the like.

In the present specification, a numerical range expressed using “to” means a range that includes the preceding and succeeding numerical values of “to” as the lower limit value and the upper limit value, respectively.

In the present specification, the total solid content refers to a total mass of the components remaining in a case where a solvent is excluded from all the components of a composition.

In the present specification, “(meth)acrylate” represents either or both of acrylate and methacrylate, “(meth)acryl” represents either or both of acryl and methacryl, “(meth)allyl” represents either or both of allyl and methallyl, and “(meth)acryloyl” represents either or both of acryloyl and methacryloyl.

In the present specification, a term “step” not only represents an independent step, but also includes a step which is not clearly distinguished from other steps in a case where an intended action of the step is obtained.

In the present specification, a weight-average molecular weight (Mw) and a number-average molecular weight (Mn) are each defined as a value in terms of polystyrene through measurement by means of gel permeation chromatography (GPC).

In the present specification, a pigment means an insoluble compound which is sparingly soluble in a specific solvent. It typically means a compound which exists in a state where it is dispersed as particles in a composition. The pigment used in the present invention preferably has a solubility at 25° C. of, for example, 0.1 g/100 g Solvent or less in either of propylene glycol monomethyl ether acetate and water.

### <Photosensitive Composition>

The photosensitive composition of an embodiment of the present invention includes:
a white or colorless pigment A,
an alkali-soluble resin B,
a polymerizable compound C having an ethylenically unsaturated double bond,
a photopolymerization initiator D1 having a light absorption coefficient of 1.0×10³ mL/gcm or more at a wavelength of 365 nm in methanol, and
a photopolymerization initiator D2 having a light absorption coefficient of 1.0×10² mL/gcm or less at a wavelength of 365 nm in methanol and a light absorption coefficient of 1.0×10³ mL/gcm or more at a wavelength of 254 nm,
in which the mass ratio of the photopolymerization initiator D1 to the photopolymerization initiator D2 is photopolymerization initiator D1 :photopolymerization initiator D2=90:10 to 40:60.

By using the photosensitive composition of the embodiment of the present invention, it is possible to form a pattern having excellent solvent resistance and rectangularity. Since the photosensitive composition of the embodiment of the present invention includes the photopolymerization initiator D1 and the photopolymerization initiator D2 at the predetermined ratio as a photopolymerization initiator, the photosensitive composition can be exposed and cured in two steps before and after development. That is, by incorporating the photopolymerization initiator D1 and the photopolymerization initiator D2 at the predetermined ratio as a photopolymerization initiator into the photosensitive composition of the embodiment of the present invention, it is possible to appropriately cure the photosensitive composition in the first exposure (exposure before development). As a result, a pattern having good rectangularity can be formed. Further, since the entire photosensitive composition can be approximately cured upon the next exposure (exposure after development), a pattern having excellent solvent resistance can be formed. Further, by a use of the photosensitive composition of the embodiment of the present invention, even in a case where a pattern is formed by a low-temperature process, for example, at 120° C., a pattern having excellent solvent resistance can be formed. As a result, the photosensitive composition of the embodiment of the present invention is particularly effective in a case where a pattern is formed by a low-temperature process. Hereinafter, the respective components of the photosensitive composition of the embodiment of the present invention will be described.

### <<White or Colorless Pigment (White Series Pigment)>>

The photosensitive composition of the embodiment of the present invention contains a white or colorless pigment (hereinafter also referred to as a white series pigment). Examples of the white series pigment include particles of oxides including at least one element selected from Ti, Zr, Sn, Sb, Cu, Fe, Mn, Pb, Cd, As, Cr, Hg, Zn, Al, Mg, Si, P, or S, and the white series pigment is preferably in the form of particles of oxides including at least one element selected from Ti, Zr, Sn, Al, or Si. As the oxide, titanium oxide or zirconium oxide is preferable, and titanium oxide is more preferable. Further, examples of the titanium oxide include rutile-type titanium oxide, anatase-type titanium oxide, and amorphous titanium oxide, and the titanium oxide is preferably the rutile-type titanium oxide. Further, a case where the oxide is surface-treated with a surface treatment agent is also preferable. Examples of the surface treatment agent include an inorganic compound and an organic compound. The inorganic compound and the organic compound may be used in combination. Specific examples of the surface treatment agent include a polyol, aluminum oxide, aluminum hydroxide, amorphous silica, hydrous silica, alkanolamine, stearic acid, organosiloxane, zirconium oxide, hydrogenphosphite dimethicone, a silane coupling agent, and a titanate coupling agent.

The shape of the white series pigment is not particularly limited. Examples thereof include shapes such as an isotropic shape (for example, a spherical shape and a polyhedral shape), an anisotropic shape (for example, a needle-like shape, a rod-like shape, and a plate-like shape), and an amorphous shape.

The weight-average particle diameter of the primary particles of the white series pigment is preferably 150 nm or less, more preferably 100 nm or less, and still more preferably 80 nm or less. The lower limit value is not particularly limited, but is preferably 1 nm or more. In addition, the weight-average particle diameter of a white series pigment refers to a value obtained by diluting a mixed solution or dispersion liquid including the white series pigment 80-fold with propylene glycol monomethyl ether acetate, and then performing measurement of an average particle diameter regarding the obtained diluted solution using a dynamic light scattering method. This measurement is performed using MICROTRACK (registered trade name) UPA-EX150 manufactured by Nikkiso Co., Ltd. to obtain a weight-average particle diameter.

The specific surface area of the white series pigment is preferably 10 to 400 m²/g, more preferably 20 to 200 m²/g, and still more preferably 30 to 150 m²/g.

The refractive index of the white series pigment is preferably 1.6 to 3.0. The lower limit is preferably 1.7 or more, and more preferably 1.8 or more. The upper limit is preferably 2.9 or less, and more preferably 2.8 or less. Further, a method for measuring the refractive index of the white series pigment is in accordance with Japanese Industrial Standard (JIS K 0062:1992).

Commercially available products may be preferably used as the white series pigment. Examples of the commercially available products of titanium oxide include TTO series (TTO-51(A), TTO-51(C), TTO-55(C), and the like), TTO-S and TTO-V series (TTO-S-1, TTO-S-2, TTO-V-3, and the like) (all trade names, manufactured by ISHIHARA SANGYO KAISHA, Ltd.), and MT series (MT-01, MT-05, and the like) (trade names, manufactured by TAYCA CORPORATION).

The content of the white series pigment is preferably 20% to 70% by mass in the total solid content of the photosensitive composition. The lower limit is more preferably 25% by mass or more, and still more preferably 30% by mass or more. The upper limit is more preferably 65% by mass or less, and still more preferably 60% by mass or less.

### <<Resin<<

The photosensitive composition of the embodiment of the present invention includes a resin. Examples of the resin include an alkali-soluble resin. The resin is blended in, for example, an application for dispersing particles such as a pigment in the composition or an application as a binder. Incidentally, a resin which is usually used for dispersing particles such as a pigment is also referred to as a dispersant. However, such applications of the resin are only exemplary, and the resin can also be used for other purposes, in addition to the above-mentioned applications.

The content of the resin in the photosensitive composition of the embodiment of the present invention is preferably 1% to 80% by mass with respect to the total solid content of the photosensitive composition. The lower limit is more preferably 5% by mass or more, and still more preferably 10% by mass or more. The upper limit is more preferably 70% by mass or less, and still more preferably 60% by mass or less.

### (Alkali-Soluble Resin)

The photosensitive composition of the embodiment of the present invention includes an alkali-soluble resin. The alkali-soluble resin can be appropriately selected from resins having a group enhancing alkali solubility. Examples of the group enhancing alkali solubility (hereinafter also referred to as an acid group) include a carboxyl group, a phosphoric acid group, a sulfo group, and a phenolic hydroxyl group, with the carboxyl group being preferable. The alkali-soluble resin may have one kind or two or more kinds of the acid groups.

The weight-average molecular weight (Mw) of the alkali-soluble resin is preferably 5,000 to 100,000. Further, the number-average molecular weight (Mn) of the alkali-soluble resin is preferably 1,000 to 20,000.

The acid value of the alkali-soluble resin is preferably 25 to 200 mgKOH/g. The lower limit is more preferably 30 mgKOH/g or more, and still more preferably 40 mgKOH/g or more. The upper limit is more preferably 150 mgKOH/g or less, still more preferably 120 mgKOH/g or less, and particularly preferably 100 mgKOH/g or less.

From the viewpoint of heat resistance, a polyhydroxystyrene-based resin, a polysiloxane-based resin, an acrylic resin, an acrylamide-based resin, and an acryl/acrylamide copolymer resin are preferable as the alkali-soluble resin. Further, from the viewpoint of controlling developability, an acrylic resin, an acrylamide-based resin, and an acryl/acrylamide copolymer resin are preferable.

As the alkali-soluble resin, a polymer having a carboxyl group in a side chain is preferable. Examples thereof include a copolymer having a repeating unit derived from monomers such as methacrylic acid, acrylic acid, itaconic acid, crotonic acid, maleic acid, 2-carboxyethyl (meth)acrylic acid, vinylbenzoic acid, and partially esterified maleic acid, an alkali-soluble phenol resin or the like such as a novolac resin, an acidic cellulose derivative having a carboxyl group in a side chain, and a polymer obtained by adding an acid anhydride to a polymer having a hydroxyl group. In particular, a copolymer of a (meth)acrylic acid and another monomer copolymerizable with the (meth)acrylic acid is suitable as the alkali-soluble resin. Examples of another monomer copolymerizable with a (meth)acrylic acid include alkyl (meth)acrylate, aryl (meth)acrylate, and a vinyl compound. Examples of the alkyl (meth)acrylate and the aryl (meth)acrylate include methyl (meth)acrylate, ethyl (meth)acrylate, propyl (meth)acrylate, butyl (meth)acrylate, isobutyl (meth)acrylate, pentyl (meth)acrylate, hexyl (meth)acrylate, octyl (meth)acrylate, phenyl (meth)acrylate, benzyl (meth)acrylate, tolyl (meth)acrylate, naphthyl (meth)acrylate, cyclohexyl (meth)acrylate, glycidyl methacrylate, and tetrahydrofurfuryl methacrylate. Examples of the vinyl compound include styrene, a-methylstyrene, vinyltoluene, acrylonitrile, vinyl acetate, N-vinylpyrrolidone, a polystyrene macromonomer, and a polymethyl methacrylate macromonomer. Further, examples of other monomer include the N-position-substituted maleimide monomers described in JP1998-300922A (JP-H10-300922A), such as N-phenylmaleimide and N-cyclohexylmaleimide. Such other monomers copolymerizable with (meth)acrylic acids may be of one kind or of two or more kinds thereof.

As the alkali-soluble resin, a benzyl (meth)acrylate/(meth)acrylic acid copolymer, benzyl (meth)acrylate/(meth)acrylic acid/2-hydroxyethyl (meth)acrylate copolymer, or a multicomponent copolymer formed of benzyl (meth)acrylate/(meth)acrylic acid/other monomers can also be preferably used. Further, a copolymer formed by copolymerizing 2-hydroxyethyl (meth)acrylate and other monomers, a 2-hydroxypropyl (meth)acrylate/polystyrene macromonomer/benzyl methacrylate/methacrylic acid copolymer described in JP1995-140654A (JP-H07-140654A), a 2-hydroxy-3-phenoxypropylacrylate/polymethyl methacrylate macromonomer/benzyl methacrylate/methacrylic acid copolymer, a 2-hydroxyethyl methacrylate/polystyrene macromonomer/methyl methacrylate/methacrylic acid copolymer, a 2-hydroxyethyl methacrylate/polystyrene macromonomer/benzyl methacrylate/methacrylic acid copolymer, and the like can also be preferably used.

As the alkali-soluble resin, an alkali-soluble resin having a polymerizable group may be used. Examples of the polymerizable group include a (meth)allyl group and a (meth)acryloyl group. As the alkali-soluble resin having a polymerizable group, an alkali-soluble resin having a polymerizable group on a side chain thereof, and the like are useful. Examples of commercially available products of the alkali-soluble resin having a polymerizable group include DIANAL NR Series (manufactured by Mitsubishi Rayon Co., Ltd.), PHOTOMER 6173 (carboxyl group-containing polyurethane acrylic oligomer, manufactured by Diamond Shamrock Co., Ltd.), VISCOAT R-264 and KS RESIST 106 (both of which are manufactured by Osaka Organic Chemical Industry, Ltd.), CYCLOMER P Series (for example, ACA230AA) and PLACCEL CF200 Series (both of which are manufactured by Daicel Corporation), EBECRYL 3800 (manufactured by Daicel-UCB Co., Ltd.), ACRYCURE RD-F8 (manufactured by Nippon Shokubai Co., Ltd.), and DP-1305 (manufactured by FUJI FINE CHEMICAL CO., LTD.).

As the alkali-soluble resin, an alkali-soluble resin including a repeating unit having a hydroxyl group is preferable. According to this aspect, the affinity to a developer is improved, and a pattern having excellent rectangularity is easily formed. In the alkali-soluble resin including a repeating unit having a hydroxyl group, the hydroxyl number of the alkali-soluble resin is preferably 30 to 100 mgKOH/g. The lower limit is more preferably 35 mgKOH/g or more, and still more preferably 40 mgKOH/g or more. The upper limit is more preferably 80 mgKOH/g or less. In a case where the hydroxyl number of the alkali-soluble resin is within the range, a pattern having excellent rectangularity is easily formed. Examples of the alkali-soluble resin including a repeating unit having a hydroxyl group include resins having the following structures.

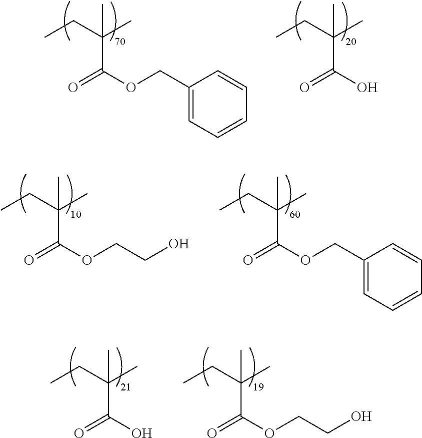

It is also preferable that the alkali-soluble resin includes a polymer formed by polymerizing monomer components including at least one compound selected from a compound represented by Formula (ED1) and the compound represented by Formula (1) of JP2010-168539A (these compounds are hereinafter also referred to as an “ether dimer” in some cases).

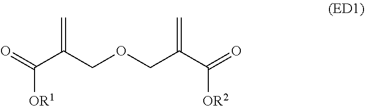

In Formula (ED1), R¹ and R² each independently represent a hydrogen atom or a hydrocarbon group having 1 to 25 carbon atoms, which may have a substituent.

With regard to specific examples of the ether dimer, reference can be made to paragraph No. 0317 of JP2013-029760A, the contents of which are incorporated herein by reference. These ether dimers may be of one kind or of two or more kinds.

Examples of the polymer formed by polymerization of monomer components including ether dimers include polymers having the following structures.

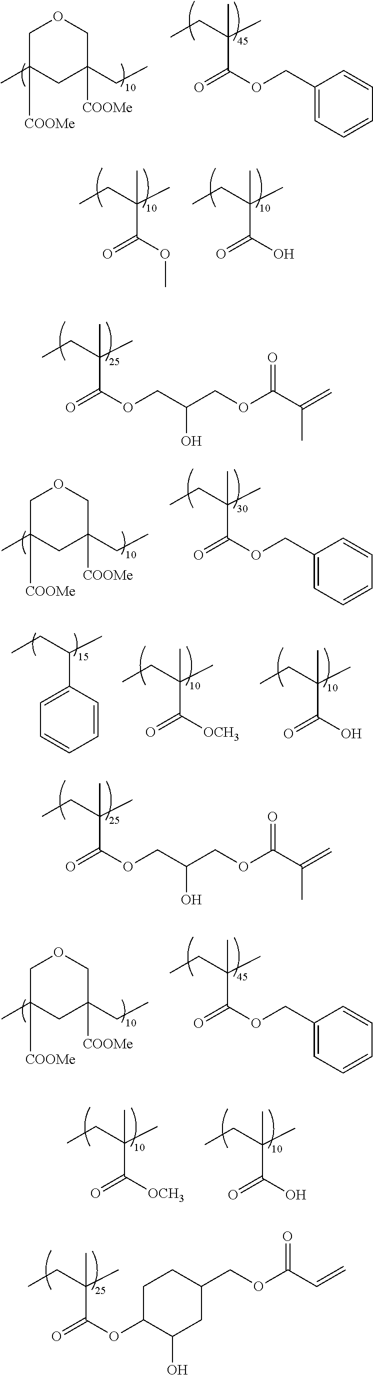

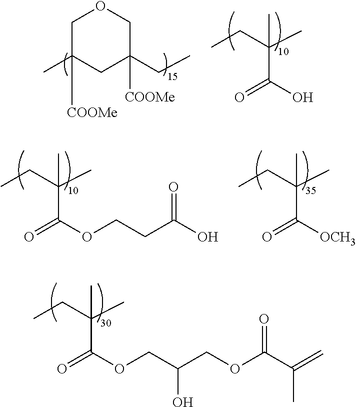

The alkali-soluble resin may include a repeating unit derived from a compound represented by Formula (X).

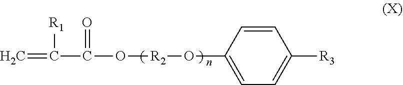

In Formula (X), RI represents a hydrogen atom or a methyl group, R₂ represents an alkylene group having 2 to 10 carbon atoms, and R₃ represents a hydrogen atom or an alkyl group having 1 to 20 carbon atoms, which may include a benzene ring. n represents an integer of 1 to 15.

With regard to the alkali-soluble resin, reference can be made to the description in paragraph Nos. 0558 to 0571 of JP2012-208494A (paragraph Nos. 0685 to 0700 of the corresponding US2012/0235099A), the contents of which are incorporated herein by reference. In addition, the copolymers (B) described in paragraph Nos. 0029 to 0063 of JP2012-032767A and the alkali-soluble resins used in Examples of the document, the binder resins described in paragraph Nos. 0088 to 0098 of JP2012-208474A and the binder resins used in Examples of the document, the binder resins described in paragraph Nos. 0022 to 0032 of JP2012-137531A and the binder resins used in Examples of the document, the binder resins described in paragraph Nos. 0132 to 0143 of JP2013-024934A and Examples of the document, the binder resins described in paragraph Nos. 0092 to 0098 of JP2011-242752A and the binder resins used in Examples of the document, or the binder resins described in paragraph Nos. 0030 to 0072 of JP2012-032770A can be used, and the contents of these publications are incorporated herein by reference.

The content of the alkali-soluble resin is preferably 1% to 50% by mass with respect to the total solid content of the photosensitive composition. The lower limit is more preferably 2% by mass or more, and still more preferably 3% by mass or more. The upper limit is more preferably 40% by mass or less, and still more preferably 35% by mass or less. The photosensitive composition of the embodiment of the present invention may include one kind or two or more kinds of the alkali-soluble resins. In a case where two or more kinds of the alkali-soluble resins are included, the total amount thereof is preferably within the range.

Furthermore, the content of the alkali-soluble resin including a repeating unit having a hydroxyl group is preferably 1% to 50% by mass with respect to the total solid content of the photosensitive composition. The lower limit is preferably 2% by mass or more, and still more preferably 3% by mass or more. The upper limit is more preferably 40% by mass or less, and still more preferably 35% by mass or less. The photosensitive composition of the embodiment of the present invention ma may include one kind or two or more kinds of the alkali-soluble resins. In a case where two or more kinds of the alkali-soluble resins are included, the total amount thereof is preferably within the range.

### (Dispersant)

The photosensitive composition of the embodiment of the present invention can contain a resin as a dispersant. Examples of the dispersant include an acidic dispersant (acidic resin) and a basic dispersant (basic resin).

Here, the acidic dispersant (acidic resin) indicates a resin in which the amount of acid groups is more than that of basic groups. As the acidic dispersant (acidic resin), a resin in which the amount of the acid groups is 70% by mole or more with respect to 100% by mole of the total amount of the acid groups and the basic groups is preferable, and a resin which is only substantially composed of acid groups is more preferable. The acid group contained in the acidic dispersant (acidic resin) is preferably a carboxyl group. The acid value of the acidic dispersant (acidic resin) is preferably 10 to 105 mgKOH/g.

Furthermore, the basic dispersant (basic resin) indicates resin in which the amount of acid groups is more than that of basic groups. As the basic dispersant (basic resin), a resin in which the amount of the basic groups is more than 50% by mole with respect to 100% by mole of the total amount of the acid groups and the basic groups is preferable. The basic group contained in the basic dispersant is preferably an amino group.

Examples of the dispersant include a polymer dispersant [for example, a polyamidoamine and a salt thereof, a polycarboxylic acid and a salt thereof, a high-molecular-weight unsaturated acid ester, a modified polyurethane, a modified polyester, a modified poly(meth)acrylate, a (meth)acrylic copolymer, and a naphthalene sulfonic acid-formalin polycondensate], a polyoxyethylene alkyl phosphoric ester, a polyoxyethylene alkyl amine, and an alkanolamine. The polymer dispersants can further be classified into a linear polymer, a terminal-modified polymer, a graft type polymer, and a block type polymer, depending on its structure. The polymer dispersant is adsorbed on a surface of a pigment and acts so as to prevent re-aggregation. For this reason, examples of a preferred structure thereof include a terminal-modified polymer, a graft-type polymer, and a block-type polymer, which have an anchoring site on a surface of a pigment. In addition, the dispersants described in paragraph Nos. 0028 to 0124 of JP2011-070156A, or the dispersants described in JP2007-277514A are also preferably used, and the contents of the publications are incorporated herein by reference.

In the present invention, a graft copolymer can also be used as the dispersant. With regard to the details of the graft copolymer, reference can be made to the description in paragraph Nos. 0131 to 0160 of JP2012-137564A, the contents of which are incorporated herein by reference. Further, as the graft copolymer, the following resins can also be used.

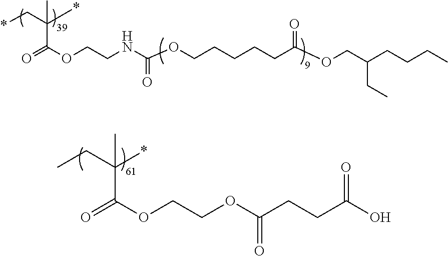

As the dispersant, commercially available products can also be used. For example, the products described in paragraph No. 0129 of JP2012-137564A can also be used as the dispersant.

The content of the dispersant is preferably 1 to 200 parts by mass with respect to 100 parts of the pigment. The lower limit is preferably 5 parts by mass or more, and more preferably 10 parts by mass or more. The upper limit is preferably 150 parts by mass or less, and more preferably 100 parts by mass or less.

### (Other Resins)

The photosensitive composition of the embodiment of the present invention can contain resins (also referred to as other resins) other than the above-mentioned dispersants or alkali-soluble resins as the resin. Examples of such other resins include a (meth)acrylic resin, a (meth)acrylamide resin, an ene-thiol resin, a polycarbonate resin, a polyether resin, a polyarylate resin, a polysulfone resin, a polyethersulfone resin, a polyphenylene resin, a polyarylene ether phosphine oxide resin, a polyimide resin, a polyamideimide resin, a polyolefin resin, a cyclic olefin resin, polyester resin, a styrene resin, and a siloxane resin. These resins may be used singly or as a mixture of two or more kinds thereof.

### <<Polymerizable Compound Having Ethylenically Unsaturated Double Bond>>

The photosensitive composition of the embodiment of the present invention contains a polymerizable compound having an ethylenically unsaturated double bond (hereinafter also referred to as a polymerizable compound). Examples of the ethylenically unsaturated bond group include a vinyl group, a (meth)allyl group, a (meth)acryloyl group, and a (meth)acryloyloxy group. In the present invention, the polymerizable compound is preferably a radically polymerizable compound.

The polymerizable compound may be any one of chemical forms such as a monomer, a prepolymer, and an oligomer, but is preferably a monomer. The molecular weight of the polymerizable compound is preferably 100 to 3,000. The upper limit is preferably 2,000 or less, and more preferably 1,500 or less. The lower limit is preferably 150 or more, and more preferably 250 or more. The polymerizable compound is preferably a bifunctional to pentadecafunctional (meth)acrylate compound, and more preferably a bifunctional to hexafunctional (meth)acrylate compound.

Examples of the polymerizable compound include the compounds described in paragraph Nos. 0095 to 0108 of JP2009-288705A, paragraph No. 0227 of JP2013-029760A, and paragraph Nos. 0254 to 0257 of JP2008-292970A, the contents of which are incorporated herein by reference.

As the polymerizable compound, dipentaerythritol triacrylate (KAYARAD D-330 as a commercially available product; manufactured by Nippon Kayaku Co., Ltd.), dipentaerythritol tetraacrylate (KAYARAD D-320 as a commercially available product; manufactured by Nippon Kayaku Co., Ltd.), dipentaerythritol penta(meth)acrylate (KAYARAD D-310 as a commercially available product; manufactured by Nippon Kayaku Co., Ltd.), dipentaerythritol hexa(meth)acrylate (KAYARAD DPHA as a commercially available product; manufactured by Nippon Kayaku Co., Ltd., A-DPH-12E manufactured by Shin-Nakamura Chemical Co., Ltd.), and a structure in which these (meth)acryloyl groups are bonded via an ethylene glycol and/or propylene glycol residue (for example, SR454 and SR499, commercially available from Sartomer Company, Inc.) are preferable. Oligomer types of these can also be used. Furthermore, as the polymerizable compound, a trifunctional (meth)acrylate compound such as trimethylolpropane tri(meth)acrylate, trimethylolpropane propyleneoxide-modified tri(meth)acrylate, trimethylolpropane ethyleneoxide-modified tri(meth)acrylate, isocyanuric acid ethyleneoxide-modified tri(meth)acrylate, and pentaerythritol tri(meth)acrylate can also be preferably used. Examples of commercially available products of the trifunctional (meth)acrylate compound include ARONIX M-309, M-310, M-321, M-350, M-360, M-313, M-315, M-306, M-305, M-303, M-452, and M-450 (manufactured by Toagosei Chemical Industry Co., Ltd.), NK Ester A9300, A-GLY-9E, A-GLY-20E, A-TMM-3, A-TMM-3L, A-TMM-3LM-N, A-TMPT, TMPT, and A-TMMT (manufactured by Shin-Nakamura Chemical Co., Ltd.), and KAYARAD GPO-303, TMPTA, THE-330, TPA-330, and PET-30 (manufactured by Nippon Kayaku Co., Ltd.).

As the polymerizable compound, a polymerizable compound having an acid group can be used. By using the polymerizable compound having an acid group, the photosensitive composition in the unexposed areas are easily removed during the development, and thus, generation of development residues can be suppressed. Examples of the acid group include a carboxyl group, a sulfo group, and a phosphoric acid group, and the carboxyl group is preferable. Examples of a commercially available product of the polymerizable compound having an acid group include ARONIX M-510 and M-520 (manufactured by Toagosei Chemical Industry Co., Ltd.).

The acid value of the polymerizable compound having an acid group is preferably 0.1 to 40 mgKOH/g, and more preferably 5 to 30 mgKOH/g. In a case where the acid value of the polymerizable compound is 0.1 mgKOH/g or more, the solubility of the photosensitive composition in a developer is good, whereas in a case where the acid value is 40 mgKOH/g or less, it is advantageous in production or handling. In addition, the curability of the photosensitive composition is excellent.

As the polymerizable compound, a compound having a caprolactone structure is also preferably used. Further, as the polymerizable compound, a polymerizable compound having an alkyleneoxy group is also preferably used. The polymerizable compound having an alkyleneoxy group is preferably a polymerizable compound having an ethyleneoxy group and/or a propyleneoxy group, more preferably a polymerizable compound having an ethyleneoxy group, and still more preferably a trifunctional to hexafunctional (meth)acrylate compound having 4 to 20 ethyleneoxy groups. Examples of the commercially available product of the polymerizable compound having an alkyleneoxy group include SR-494 which is a tetrafunctional (meth)acrylate having four ethyleneoxy groups, manufactured by Sartomer Co., Inc., and KAYARAD TPA-330 which is a trifunctional (meth)acrylate having three isobutyleneoxy groups.

As the polymerizable compound, the urethane acrylates as described in JP1973-041708B (JP-S48-041708B), JP1976-037193A (JP-S51-037193A), JP1990-032293B (JP-H02-032293B), and JP1990-016765B (JP-H02-016765B), and the urethane compounds having an ethylene oxide-based skeleton described in JP1983-049860B (JP-S58-049860B), JP1981-017654B (JP-S56-017654B), JP1987-039417B (JP-S62-039417B), and JP1987-039418B (JP-S62-039418B) are also suitable. In addition, the addition-polymerizable compounds having an amino structure or a sulfide structure in a molecule, which are described in JP1988-277653A (JP-S63-277653A), JP1988-260909A (JP-S63-260909A), and JP1989-105238A (JP-H01-105238A) are also preferably used. Examples of a commercially available product thereof include urethane oligomers UAS-10 and UAB-140 (manufactured by Sanyo-kokusaku Pulp Co., Ltd.), UA-7200 (manufactured by Shin-Nakamura Chemical Co., Ltd.), DPHA-40H (manufactured by Nippon Kayaku Co., Ltd.), and UA-306H, UA-306T, UA-306I, AH-600, T-600, and AI-600 (manufactured by Kyoeisha Chemical Co., Ltd.).

The content of the polymerizable compound is preferably 0.1% to 50% by mass with respect to the total solid content of the photosensitive composition. The lower limit is, for example, more preferably 0.5% by mass or more, and still more preferably 1% by mass or more. The upper limit is, for example, more preferably 45% by mass or less, and still more preferably 40% by mass or less. The polymerizable compounds may be used singly or in combination of two or more kinds thereof. In a case where the polymerizable compounds are used in combination of two or more kinds thereof, the total amount thereof preferably falls within the range.

### <<Compound Having Epoxy Group>>

The photosensitive composition of the embodiment of the present invention preferably further contains a compound having an epoxy group. According to the aspect, the mechanical strength or the like of a film can be improved. The compound having an epoxy group is preferably a compound having two or more epoxy groups per molecule. The number of epoxy groups per molecule is preferably 2 to 100. The upper limit can be set to, for example, 10 or less, or to 5 or less.

The epoxy equivalent of the compound having an epoxy group (=the molecular weight of the compound having an epoxy group/the number of epoxy groups) is preferably 500 g/eq or less, more preferably 100 to 400 g/eq, and still more preferably 100 to 300 g/eq.

The compound having an epoxy group may be either a low-molecular-weight compound (for example, a molecular weight of less than 1,000) or a high-molecular-weight compound (macromolecule) (for example, a molecular weight of 1,000 or more, and in a case of a polymer, a weight-average molecular weight of 1,000 or more). The molecular weight of the compound having an epoxy group (a weight-average molecular weight thereof in a case where the compound is a polymer) is preferably 200 to 100,000, and more preferably 500 to 50,000. The upper limit of the molecular weight (in a case of a polymer, the weight-average molecular weight) is preferably 3,000 or less, more preferably 2,000 or less, and still more preferably 1,500 or less.

As the compound having an epoxy group, the compounds described in paragraph Nos. 0034 to 0036 of JP2013-011869A, paragraph Nos. 0147 to 0156 of JP2014-043556A, or paragraph Nos. 0085 to 0092 of JP2014-089408A can also be used. The contents of the publications are incorporated herein by reference.

In a case where the photosensitive composition of the embodiment of the present invention contains a compound having an epoxy group, the content of the compound having an epoxy group is preferably 0.1% to 40% by mass with respect to the total solid content of the photosensitive composition. The lower limit is, for example, more preferably 0.5% by mass or more, and still more preferably 1% by mass or more. The upper limit is, for example, more preferably 30% by mass or less, and still more preferably 20% by mass or less. The compound having an epoxy group may be used singly or in combination of two or more kinds thereof In a case where the polymerizable compound is used in combination of two or more kinds thereof, the total amount thereof is preferably within the range. In addition, the mass ratio of the polymerizable compound to the compound having an epoxy group is preferably the mass of the polymerizable compound D:the mass of the compound having an epoxy group=100:1 to 100:400, more preferably 100:1 to 100:100, and still more preferably 100:1 to 100:50.

### <<Solvent>>

The photosensitive composition of the embodiment of the present invention preferably contains a solvent. The solvent is preferably an organic solvent. The solvent is not particularly limited as long as it satisfies the solubility of the respective components or the coatability of the photosensitive composition.

Suitable examples of the organic solvent include esters such as ethyl acetate, n-butyl acetate, isobutyl acetate, cyclohexyl acetate, amyl formate, isoamyl acetate, butyl propionate, isopropyl butyrate, ethyl butyrate, butyl butyrate, methyl lactate, ethyl lactate, alkyl alkyloxyacetate esters (for example, methyl alkyloxyacetate, ethyl alkyloxyacetate, and butyl alkyloxyacetate (for example, methyl methoxyacetate, ethyl methoxyacetate, butyl methoxyacetate, methyl ethoxyacetate, and ethyl ethoxyacetate)), alkyl 3-alkyloxypropionate esters (for example, methyl 3-alkyloxypropionate and ethyl 3-alkyloxypropionate (for example, methyl 3-methoxypropionate, ethyl 3-methoxypropionate, methyl 3-ethoxypropionate, and ethyl 3-ethoxypropionate)), alkyl 2-alkyloxypropionate esters (for example, methyl 2-alkyloxypropionate, ethyl 2-alkyloxypropionate, and propyl 2-alkyloxypropionate (for example, methyl 2-methoxypropionate, ethyl 2-methoxypropionate, propyl 2-methoxypropionate, methyl 2-ethoxypropionate, and ethyl 2-ethoxypropionate)), methyl 2-alkyloxy-2-methyl propionate and ethyl 2-alkyloxy-2-methyl propionate (for example, methyl 2-methoxy-2-methyl propionate and ethyl 2-ethoxy-2-methyl propionate), methyl pyruvate, ethyl pyruvate, propyl pyruvate, methyl acetoacetate, ethyl acetoacetate, methyl 2-oxobutanoate, and ethyl 2-oxobutanoate; ethers, for example, diethylene glycol dimethyl ether, tetrahydrofuran, ethylene glycol monomethyl ether, ethylene glycol monoethyl ether, methyl cellosolve acetate, ethyl cellosolve acetate, diethylene glycol monomethyl ether, diethylene glycol monoethyl ether, diethylene glycol monobutyl ether, propylene glycol monomethyl ether, propylene glycol monomethyl ether acetate, propylene glycol monoethyl ether acetate, and propylene glycol monopropyl ether acetate; ketones, for example, methyl ethyl ketone, cyclohexanone, cyclopentanone, 2-heptanone, and 3-heptanone; and aromatic hydrocarbons, for example, toluene and xylene. However, it is preferable in some cases to reduce aromatic hydrocarbons (benzene, toluene, xylene, ethylbenzene, and the like) (for example, the amount can be set to 50 parts per million (ppm) by mass or less, 10 ppm by mass or less, or 1 ppm by mass or less with respect to the total amount of the organic solvent) as a solvent for a reason such as an environmental aspect.

The organic solvents may be used singly or in combination of two or more kinds thereof. In a case where the organic solvents are used in combination of two or more kinds thereof, the solvent is particularly preferably a mixed solution formed of two or more kinds selected from methyl 3-ethoxypropionate, ethyl 3-ethoxypropionate, ethyl cellosolve acetate, ethyl lactate, diethylene glycol dimethyl ether, butyl acetate, methyl 3-methoxypropionate, 2-heptanone, cyclohexanone, ethyl carbitol acetate, butyl carbitol acetate, propylene glycol methyl ether, and propylene glycol methyl ether acetate.

In the present invention, the organic solvent preferably has a content of peroxides of 0.8 mmol/L or less, and more preferably it does not substantially include peroxides. Further, it is preferable to use an organic solvent having a small metal content, and for example, the metal content of the organic solvent is preferably 10 parts per billion (ppb) by mass or less. The metal content of the organic solvent is at a level of parts per trillion (ppt) by mass, as desired, and such a high-purity solvent is provided by, for example, Toyo Kasei Kogyo Co., Ltd. (The Chemical Daily, Nov. 13, 2015).

The content of the solvent is preferably an amount such that the total solid content of the photosensitive composition is 5% to 80% by mass. The lower limit is preferably an amount such that the total solid content of the photosensitive composition is 10% by mass or more. The upper limit is an amount such that the total solid content of the photosensitive composition is preferably 60% by mass or less, more preferably 50% by mass or less, and still more preferably 40% by mass or less.

### <<Photopolymerization Initiator>>

The photosensitive composition of the embodiment of the present invention contains a photopolymerization initiator. Examples of the photopolymerization initiator include halogenated hydrocarbon derivatives (for example, a compound having a triazine skeleton and a compound having an oxadiazole skeleton), acylphosphine compounds such as acylphosphine oxide, hexaaryl biimidazole compounds, oxime compounds such as an oxime derivative, organic peroxides, thio compounds, ketone compounds, aromatic onium salts, ketoxime ether compounds, aminoacetophenone compounds, hydroxyacetophenone compounds, a phenylglyoxylate compounds. With regard to specific examples of the photopolymerization initiator, reference can be made to the description in paragraph Nos. 0265 to 0268 of JP2013-029760A, the contents of which are incorporated herein by reference.

Examples of the phenylglyoxylate compound include methyl phenylglyoxylic ester. Examples of a commercially available product thereof include DAROCUR-MBF (manufactured by BASF).

Examples of the aminoacetophenone compound include the aminoacetophenone compounds described in JP1998-291969A (JP-H10-291969A). Further, as the aminoacetophenone compound, any of IRGACURE-907, IRGACURE-369, and IRGACURE-379 (all manufactured by BASF) can be used.

Examples of the acylphosphine compound include the acylphosphine compound described in JP4225898B. Specific examples thereof include bis(2,4,6-trimethylbenzoyl)-phenylphosphine oxide. As the acylphosphine compound, IRGACURE-819 or DAROCUR-TPO (both manufactured by BASF) can also be used.

Examples of the hydroxyacetophenone compound include a compound represented by Formula (V).

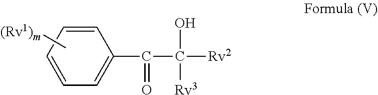

In the formula, Rv¹ represents a substituent, Rv² and Rv³ each independently represent a hydrogen atom or a substituent, Rv² and Rv³ may be bonded to each other to form a ring, and m represents an integer of 0 to 4.

Examples of the substituent represented by Rv¹ include an alkyl group (preferably an alkyl group having 1 to 10 carbon atoms) and an alkoxy group (preferably an alkoxy group having 1 to 10 carbon atoms). The alkyl group and the alkoxy group are preferably linear or branched, and more preferably linear. The alkyl group and the alkoxy group represented by Rv¹ may be unsubstituted and may have a substituent. Examples of the substituent include a hydroxyl group and a group having a hydroxyacetophenone structure. Examples of the group having a hydroxyacetophenone structure include a benzene ring bonded to Rv¹ in Formula (V) or a group with a structure obtained by removing one hydrogen atom from Rv¹.

Rv² and Rv³ each independently represent a hydrogen atom or a substituent. As the substituent, the alkyl group (preferably an alkyl group having 1 to 10 carbon atoms) is preferable. Further, Rv² and Rv³ may be bonded to form a ring (preferably a ring having 4 to 8 carbon atoms, and more preferably an aliphatic ring having 4 to 8 carbon atoms). The alkyl group is preferably linear or branched, and more preferably linear.

Specific examples of the compound represented by Formula (V) include the following compounds.

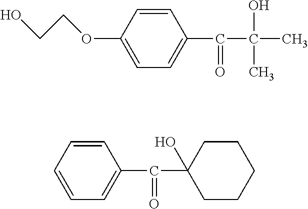 [SMILES: CC(C)(O)C(=O)c1ccc(OCCO)cc1 ; O=C(c1ccccc1)C1(O)CCCCC1]

As the hydroxyacetophenone compound, IRGACURE-184, DAROCUR-1173, IRGACURE-500, IRGACURE-2959, or IRGACURE-127 (trade names: all manufactured by BASF) can also be used.

As the oxime compound, the compound described in JP2001-233842A, the compounds described in JP2000-080068A, the compounds described in JP2006-342166A, or the like can be used. As the oxime compound, the compounds described in J. C. S. Perkin II (1979), pp. 1653 to 1660, J. C. S. Perkin II (1979), pp. 156 to 162, Journal of Photopolymer Science and Technology (1995), pp. 202 to 232, each of the publications of JP2000-066385A, JP2000-080068A, JP2004-534797A, and JP2006-342166A, or the like can also be used. Specific examples of the oxime compound include 1,2-octanedione, 1-[4-(phenylthio)-, 2-(O-benzoyloxime)], ethanone, 1-[9-ethyl-6-(2-methylbenzoyl)-9H-carbazol-3-yl]-, and 1-(O-acetyloxime). As a commercially available product thereof, IRGACURE-OXE01, IRGACURE-OXE02, IRGACURE-OXE03, or IRGACURE-OXE04 (all manufactured by BASF) is suitably used. In addition, TRONLY TR-PBG-304, TRONLY TR-PBG-309, or TRONLY TR-PBG-305 (manufactured by CHANGZHOU TRONLY NEW ELECTRONIC MATERIALS CO., LTD.), or ADEKA ARKLS NCI-930 or ADEKA OPTOMER N-1919 (the photopolymerization initiator 2 in JP2012-014052A) (both manufactured by ADEKA Corporation) can be used.

Furthermore, as the oxime compound, the compounds described in JP2009-519904A in which oxime is linked to an N-position of carbazole ring, the compounds described in U.S. Pat. No. 7,626,957B in which a hetero-substituent is introduced into a benzophenone moiety, the compounds described in JP2010-015025A and US2009/292039A in which a nitro group is introduced into a coloring agent moiety, the ketoxime compounds described in W02009/131189A, the compounds described in U.S. Pat. No. 7,556,910B, which contain a triazine skeleton and an oxime skeleton in the same molecule, or the compounds described in JP2009-221114A, which have a maximum absorption at 405 nm and have excellent sensitivity to a light source of g-rays, and the like, may be used. Preferably, reference can be made to the descriptions in, for example, paragraph Nos. 0274 to 0306 of JP2013-029760A, the contents of which are incorporated herein by reference.

An oxime compound having a fluorene ring can also be used as the oxime compound. Specific examples of the oxime compound having a fluorene ring include the compounds described in JP2014-137466A, the contents of which are incorporated herein by reference.

An oxime compound having a benzofuran skeleton can also be used as the oxime compound. Specific examples thereof include the compounds OE-01 to OE-75 described in WO2015/036910A.

An oxime compound having a fluorine atom can also be used as the oxime compound. Specific examples of the oxime compound having a fluorine atom include the compounds described in JP2010-262028A, the compounds 24, and 36 to 40 described in JP2014-500852A, and the compounds (C-3) described in JP2013-164471A, the contents of which are incorporated herein by reference.

An oxime compound having a nitro group can also be used as the oxime compound. It is also preferable that the oxime compound having a nitro group is a dimer. Specific examples of the oxime compound having a nitro group include the compounds described in paragraph Nos. 0031 to 0047 of JP2013-114249A, the compounds described in paragraph Nos. 0008 to 0012 and 0070 to 0079 of JP2014-137466A, and the compounds described in paragraph Nos. 0007 to 0025 of JP4223071B, and ADEKA ARKLS NCI-831 (manufactured by ADEKA Corporation).

Specific examples of the oxime compound are set forth below, but the present invention is not limited thereto.

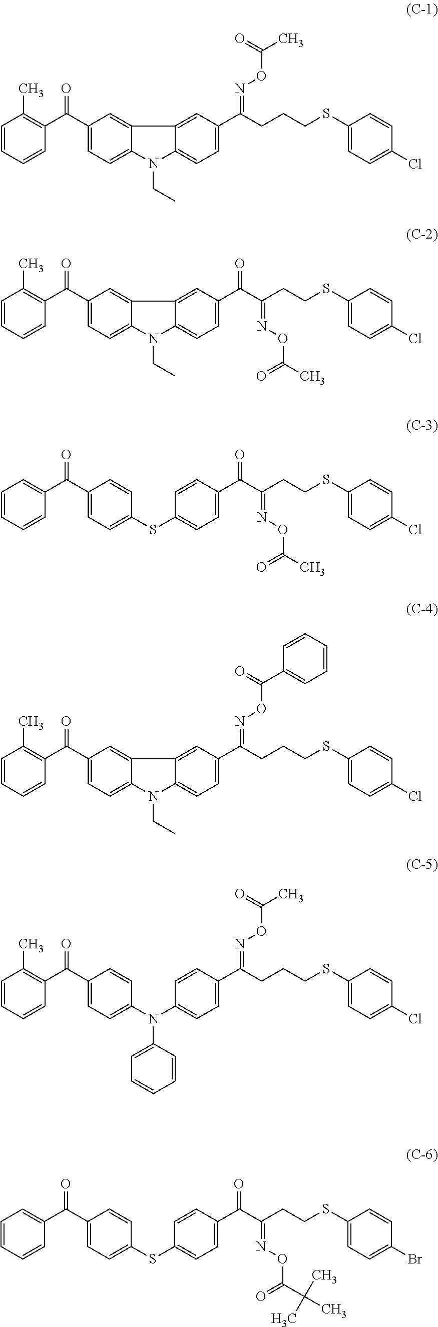 [SMILES: CCn1c2ccc(C(=O)c3ccccc3C)cc2c2cc(/C(CCCSc3ccc(Cl)cc3)=N/OC(C)=O)ccc21 ; CCn1c2ccc(C(=O)/C(CCSc3ccc(Cl)cc3)=N/OC(C)=O)cc2c2cc(C(=O)c3ccccc3C)ccc21 ; CC(=O)O/N=C(\CCSc1ccc(Cl)cc1)C(=O)c1ccc(Sc2ccc(C(=O)c3ccccc3)cc2)cc1 ; CCn1c2ccc(C(=O)c3ccccc3C)cc2c2cc(/C(CCCSc3ccc(Cl)cc3)=N/OC(=O)c3ccccc3)ccc21 ; CC(=O)O/N=C(\CCCSc1ccc(Cl)cc1)c1ccc(N(c2ccccc2)c2ccc(C(=O)c3ccccc3C)cc2)cc1 ; CC(C)(C)C(=O)O/N=C(\CCSc1ccc(Br)cc1)C(=O)c1ccc(Sc2ccc(C(=O)c3ccccc3)cc2)cc1]

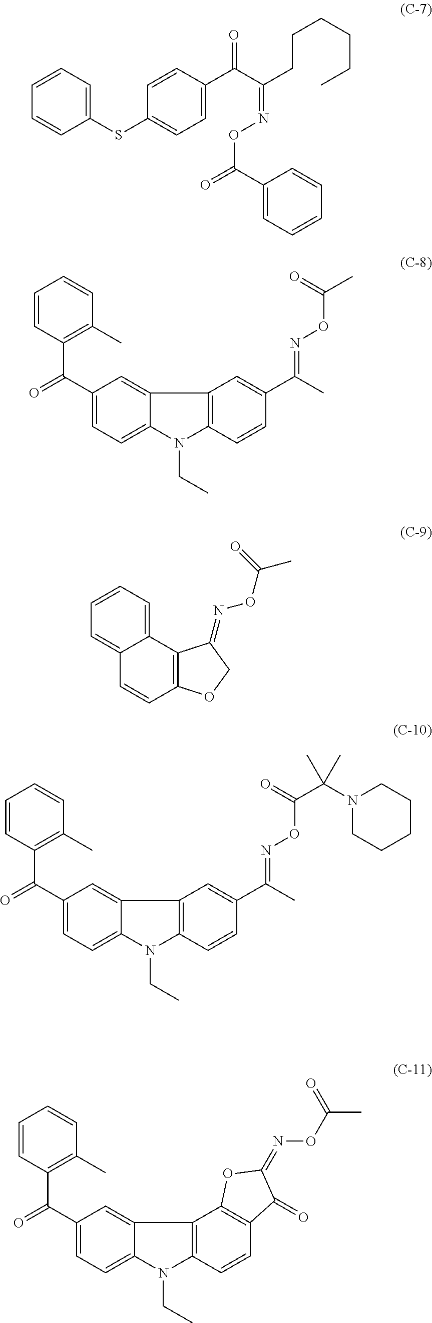

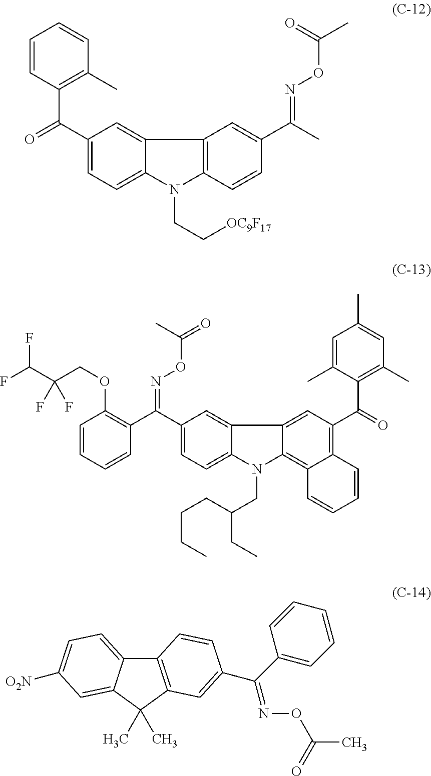

In the present invention, a photopolymerization initiator D1 having a light absorption coefficient of 1.0×10³ mL/gcm or more at a wavelength of 365 nm in methanol, and a photopolymerization initiator D2 light absorption coefficient of 1.0×10² mL/gcm or less at a wavelength of 365 nm in methanol and a light absorption coefficient of 1.0×10³ mL/gcm or more at a wavelength of 254 nm are used in combination as the photopolymerization initiator. A compound having the light absorption coefficient selected from the above-mentioned compounds is preferably used as the photopolymerization initiator D1 and the photopolymerization initiator D2.

Moreover, in the present invention, the light absorption coefficient at the wavelength of the photopolymerization initiator is a value calculated as follows. That is, the light absorption coefficient was calculated by dissolving a photopolymerization initiator in methanol to prepare a measurement solution of the photopolymerization initiator, and measuring the absorbance of the above-mentioned measurement solution. Specifically, the above-mentioned measurement solution was put into a glass cell having a width of 1 cm to measure an absorbance using a UV-Vis-NIR spectrophotometer (Cary 5000) manufactured by Agilent Technologies, Inc., and the absorbance was applied to the following equation to calculate light absorption coefficients at a wavelength of 365 nm and a wavelength of 254 nm (mL/gcm).

$$ɛ = \frac{A}{cl}$$

In the equation, ε represents a light absorption coefficient (mL/gcm), A represents an absorbance, c represents a concentration (g/mL) at the photopolymerization initiator, and l represents the length (cm) of an optical path.

The light absorption coefficient of the photopolymerization initiator D1 at a wavelength of 365 nm in methanol is 1.0×10³ mL/gcm or more, preferably 1.0×10³ to 1.0×10⁴ mL/gcm, more preferably 2.0×10³ to 9.0×10³ mL/gcm, and still more preferably 3.0×10³ to 8.0×10³ mL/gcm.

Furthermore, the light absorption coefficient of the photopolymerization initiator D1 at a wavelength of 254 nm in methanol is preferably 1.0×10⁴ to 1.0×10⁵ mL/gcm, more preferably 1.5×10⁴ to 9.5×10⁴ mL/gcm, and still more preferably 3.0×10⁴ to 8.0×10⁴ mL/gcm.

As the photopolymerization initiator D1, an oxime compound, an aminoacetophenone compound, or an acylphosphine compound is preferable, the oxime compound or the acylphosphine compound is more preferable, and the oxime compound is still more preferable. Specific examples of the photopolymerization initiator D1 include 1,2-octanedione, 1-[4-(phenylthio)-, 2-(O-benzoyloxime)] (as a commercially available product thereof, for example, IRGACURE-OXE01 manufactured by BASF), ethanone, 1[9-ethyl-6-(2-methylbenzoyl)-9H-carbazol-3-yl]-, 1-(O-acetyloxime) (as a commercially available product thereof, for example, IRGACURE-OXE02 manufactured by BASF), and bis(2,4,6-trimethylbenzoyl)-phenylphosphine oxide (as a commercially available product thereof, for example, IRGACURE-819 manufactured by BASF).

The light absorption coefficient of the photopolymerization initiator D2 at a wavelength of 365 nm in methanol is 1.0×10² mL/gcm or less, preferably 10 to 1.0×10² mL/gcm, and more preferably 20 to 1.0×10² mL/gcm. Further, a difference between the light absorption coefficient of the photopolymerization initiator D1 at a wavelength of 365 nm in methanol and the light absorption coefficient of the photopolymerization initiator D2 at a wavelength of 365 nm in methanol is 9.0×10² mL/gcm or more, preferably 9.0×10² to 1.0×10⁵ mL/gcm, and more preferably 9.0×10² to 1.0×10⁴ mL/gcm. Further, the light absorption coefficient of the photopolymerization initiator D2 at a wavelength of 254 nm in methanol is 1.0×10³ mL/gcm or more, preferably 1.0×10³ to 1.0×10⁶ mL/gcm, and more preferably 5.0×10³ to 1.0×10⁵ mL/gcm.

As the photopolymerization initiator D2, a hydroxyacetophenone compound, a phenylglyoxylate compound, an aminoacetophenone compound, or an acylphosphine compound is preferable, the hydroxyacetophenone compound or the phenylglyoxylate compound is more preferable, and the hydroxyacetophenone compound is still more preferable. Further, as the hydroxyacetophenone compound, the above-mentioned compound represented by Formula (V) is preferable.

As a combination of the photopolymerization initiator D1 and the photopolymerization initiator D2, a combination in which the photopolymerization initiator D1 is an oxime compound and the photopolymerization initiator D2 is a hydroxyacetophenone compound is preferable, and a combination in which the photopolymerization initiator D1 is an oxime compound and the photopolymerization initiator D2 is the above-mentioned compound represented by Formula (V) is more preferable. With such a combination, the rectangularity and the solvent resistance of the obtained pattern can be further improved. A reason why such an effect is obtained is that by using the oxime compound as the photopolymerization initiator D1, the sensitivity for light at a wavelength of 365 nm such as i-rays can be further enhanced. Incidentally, by using the compound represented by Formula (V) as the photopolymerization initiator D2, the sensitivity for light at a wavelength of 254 nm can be further enhanced. Further, it is considered that by using both the photopolymerization initiators in combination at a ratio specified in the present invention, a balance of the sensitivity for light at a wavelength of 365 nm such as i-rays and the sensitivity for light at a wavelength of 254 nm is good, and the above-mentioned effect is more noticeably obtained.

In the photosensitive composition of the embodiment of the present invention, the mass ratio of the photopolymerization initiator D1 to the photopolymerization initiator D2 is photopolymerization initiator D1 :photopolymerization initiator D2 =90:10 to 40:60, preferably 90:10 to 45:55, more preferably 90:10 to 55:45, still more preferably 90:10 to 60:40, and particularly preferably 85:15 to 65:35. In a case where the ratio of the both is within the range, a pattern having excellent solvent resistance and rectangularity can be formed. That is, since the ratio of the photopolymerization initiator D1 is 90 to 40, the sensitivity during formation of a pattern can be appropriately adjusted, and thus, a pattern having excellent rectangularity can be formed. Further, since the ratio of the photopolymerization initiator D2 is 10 to 60, the curability of the photosensitive composition is good, and thus, a cured film having excellent solvent resistance can be formed.

In the photosensitive composition of the embodiment of the present invention, the photopolymerization initiator D1 and the photopolymerization initiator D2 are preferably contained in a total amount of 1% to 20% by mass in the total solid content of the photosensitive composition. The lower limit is preferably 2% by mass or more, more preferably 3% by mass or more, and still more preferably 4% by mass or more. The upper limit is preferably 15% by mass or less, and more preferably 12% by mass or less.

In the photosensitive composition of the embodiment of the present invention, the photopolymerization initiator D1 and the photopolymerization initiator D2 are particularly preferably contained in a total amount of 4% to 12% by mass in the total solid content of the photosensitive composition. According to this aspect, the rectangularity and the solvent resistance of the obtained pattern can be further improved.

In the photosensitive composition of the embodiment of the present invention, photopolymerization initiators other than above-mentioned photopolymerization initiator D1 and above-mentioned photopolymerization initiator D2 (hereinafter also referred to as other photopolymerization initiators) can also be contained as the photopolymerization initiator, but it is preferable that such other photopolymerization initiators are substantially not contained. In a case where other photopolymerization initiators are substantially not contained, the content of such other photopolymerization initiators is preferably 1 part by mass or less, more preferably 0.5 parts by mass or less, and still more preferably 0.1 parts by mass or less, with respect to 100 parts by mass of the photopolymerization initiator D1 and the photopolymerization initiator D2, and even still more preferably, other photopolymerization initiators are not contained.

### <<Curing Accelerator>>

A curing accelerator may be added to the photosensitive composition of the embodiment of the present invention for the purpose of accelerating the reaction of a polymerizable compound or lowering a curing temperature. Examples of the curing accelerator include polyfunctional thiol compounds having two or more mercapto groups in a molecule thereof. The polyfunctional thiol compounds may also be added for the purpose of improving stability, odor, resolution, developability, adhesiveness, or the like. The polyfunctional thiol compounds are preferably secondary alkanethiols, and more preferably compounds having structures represented by Formula (T1).

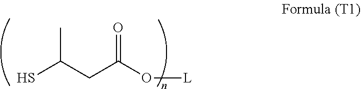

(In Formula (T1), n represents an integer of 2 to 4, and L represents a divalent to tetravalent linking group.)

In Formula (T1), it is preferable that the linking group L is an aliphatic group having 2 to 12 carbon atoms, and it is particularly preferable that n is 2 and L is an alkylene group having 2 to 12 carbon atoms. Specific examples of the polyfunctional thiol compounds are compounds represented by Structural Formulae (T2) to (T4), with the compound represented by Formula (T2) being particularly preferable. These polyfunctional thiol compounds can be used singly or in combination of two or more kinds thereof.

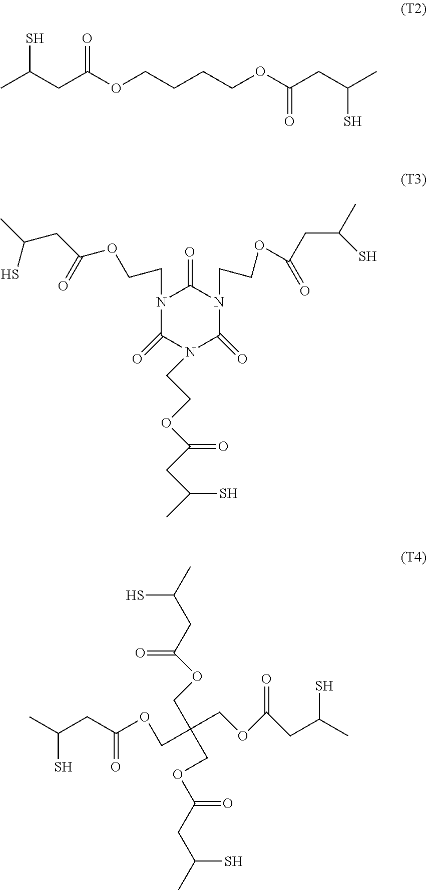

Moreover, as the curing accelerator, a methylol-based compound (for example, the compounds exemplified as a crosslinking agent in paragraph No. 0246 of JP2015-034963A), amines, phosphonium salts, amidine salts, amide compounds (each of which are the curing agents described in, for example, paragraph No. 0186 of JP2013-041165A), base generators (for example, the ionic compounds described in JP2014-055114A), cyanate compounds (for example, the compounds described in paragraph No. 0071 of JP2012-150180A), alkoxysilane compounds (for example, the alkoxysilane compounds having epoxy groups, described in JP2011-253054A), onium salt compounds (for example, the compounds exemplified as an acid generator in paragraph No. 0216 of JP2015-034963A, and the compounds described in JP2009-180949A), or the like can be used.

In a case where the photosensitive composition of the embodiment of the present invention contains a curing accelerator, the content of the curing accelerator is preferably 0.3% to 8.9% by mass, and more preferably 0.8% to 6.4% by mass, with respect to the total solid content of the photosensitive composition.

### <<Surfactant>>

From the viewpoint of further improving coatability, the photosensitive composition of the embodiment of the present invention may contain various surfactants. As the surfactant, various surfactants such as a fluorine-based surfactant, a nonionic surfactant, a cationic surfactant, an anionic surfactant, and a silicon-based surfactant can be used.

By incorporating the fluorine-based surfactant into the photosensitive composition of the embodiment of the present invention, liquid characteristics (in particular, fluidity) in a case of preparation of a coating liquid using the photosensitive composition are further improved, and thus, the evenness of coating thickness or liquid saving properties can be further improved. That is, in a case where a film is formed using the coating liquid to which a photosensitive composition containing the fluorine-based surfactant has been applied, the interface tension between a surface to be coated and the coating liquid is reduced to improve wettability with respect to the surface to be coated, and enhance coatability with respect to the surface to be coated. Therefore, formation of a film with a uniform thickness which exhibits little thickness unevenness can be more suitably performed.

The fluorine content in the fluorine-based surfactant is preferably 3% to 40% by mass, more preferably 5% to 30% by mass, and particularly preferably 7% to 25% by mass. The fluorine-based surfactant in which the fluorine content falls within this range is effective in terms of the evenness of the thickness of the coating film or liquid saving properties, and the solubility of the surfactant in the photosensitive composition is also good.

Examples of the fluorine-based surfactant include MEGAFACE F171, F172, F173, F176, F177, F141, F142, F143, F144, R30, F437, F475, F479, F482, F554, and F780 (all manufactured by DIC Corporation), FLUORAD FC430, FC431, and FC171 (all manufactured by Sumitomo 3M), SURFLON S-382, SC-101, SC-103, SC-104, SC-105, SC-1068, SC-381, SC-383, and S-393, and SURFLON KH-40 (all manufactured by Asahi Glass Co., Ltd.), and PF636, PF656, PF6320, PF6520, and PF7002 (all manufactured by OMNOVA). Further, as the fluorine-based surfactant, the compounds described in paragraph Nos. 0015 to 0158 of JP2015-117327A, and the compounds described in paragraph Nos. 0117 to 0132 of JP2011-132503A can be used. As the fluorine-based surfactant, a block polymer can also be used, and specific examples thereof include the compounds described in JP2011-089090A.

As the fluorine-based surfactant, an acrylic compound in which by application of heat to a molecular structure containing a functional group having a fluorine atom, in which a part of the functional group containing a fluorine atom is cut to volatilize a fluorine atom, can also be suitably used. Examples of the fluorine-based surfactant include MEGAFACE DS series (manufactured by DIC Corporation, The Chemical Daily, February 22, 2016) (Nikkei Business Daily, Feb. 23, 2016), for example, MEGAFACE DS-21.

As the fluorine-based surfactant, a fluorine-containing polymer compound including a repeating unit derived from a (meth)acrylate compound having a fluorine atom and a repeating unit derived from a (meth)acrylate compound having 2 or more (preferably 5 or more) alkyleneoxy groups (preferably ethyleneoxy groups or propyleneoxy groups) can also be preferably used, and the following compounds are also exemplified as a fluorine-based surfactant for use in the present invention. In the following in the formula, % representing the ratio of the repeating unit is % by mole.

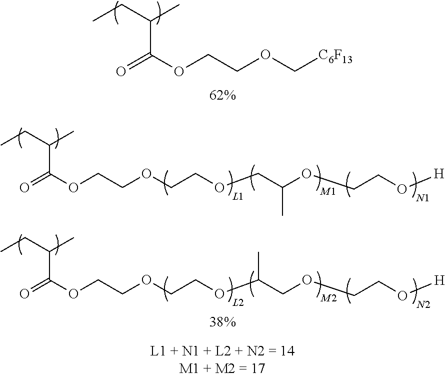

The weight-average molecular weight of the compounds is preferably 3,000 to 50,000, and is, for example 14,000.

A fluorine-containing polymer having an ethylenically unsaturated bond group in a side chain can also be used as the fluorine-based surfactant. Specific examples thereof include the compounds described in paragraph Nos. 0050 to 0090 and paragraph Nos. 0289 to 0295 of JP2010-164965A. Examples of commercially available products thereof include MEGAFACE RS-101, RS-102, RS-718-K, and RS-72-K, all of which are manufactured by DIC Corporation.

Examples of the nonionic surfactant include glycerol, trimethylolpropane, trimethylolethane, and ethoxylate and propoxylate thereof (for example, glycerol propoxylate and glycerol ethoxylate), polyoxyethylene lauryl ether, polyoxyethylene stearyl ether, polyoxyethylene oleyl ether, polyoxyethylene octyl phenyl ether, polyoxyethylene nonyl phenyl ether, polyethylene glycol dilaurate, polyethylene glycol distearate, sorbitan fatty acid esters, PLURONIC L10, L31, L61, L62, 10R5, 17R2, and 25R2 (manufactured by BASF), TETRONIC 304, 701, 704, 901, 904, and 150R1 (manufactured by BASF), SOLSEPERSE 20000 (manufactured by Lubrizol Japan Ltd.), NCW-101, NCW-1001, and NCW-1002 (manufactured by Wako Pure Chemical Industries, Ltd.), PIONIN D-6112, D-6112-W, and D-6315 (manufactured by Takemoto Oil & Fat Co., Ltd.), and OLFINE E1010, and SURFYNOL 104, 400, and 440 (manufactured by Nissin chemical industry Co., Ltd.).

Examples of the cationic surfactant include an organosiloxane polymer KP341 (manufactured by Shin-Etsu Chemical Co., Ltd.), a (meth)acrylic acid-based (co)polymer POLYFLOW No. 75, No. 90, and No. 95 (manufactured by KYOEISHA CHEMICAL CO., LTD.), and W001 (manufactured by Yusho Co., Ltd.).

Examples of the anionic surfactant include W004, W005, and W017 (manufactured by Yusho Co., Ltd.), and BL (manufactured by Sanyo Chemical Industries, Ltd.).

Examples of the silicon-based surfactant include TORAY SILICONE DC3PA, TORAY SILICONE SH7PA, TORAY SILICONE DC11PA, TORAY SILICONE SH21PA, TORAY SILICONE SH28PA, TORAY SILICONE SH29PA, TORAY SILICONE SH30PA, and TORAY SILICONE SH8400 (all manufactured by Dow Corning Toray Co., Ltd.), TSF-4440, TSF-4300, TSF-4445, TSF-4460, and TSF-4452 (all manufactured by Momentive Performance Materials Co., Ltd.), KP341, KF6001, and KF6002 (all manufactured by Shin-Etsu Chemical Co., Ltd.), and BYK307, BYK323, and BYK330 (all manufactured by BYK Chemie).

The surfactants may be used singly or in combination of two or more kinds thereof.

The content of the surfactant is preferably 0.001% to 2.0% by mass, and more preferably 0.005% to 1.0% by mass, with respect to the total solid content of the photosensitive composition.

### <<Silane Coupling Agent>>

The photosensitive composition of the embodiment of the present invention can contain a silane coupling agent. As the silane coupling agent, a silane compound having at least two kinds of functional groups having different reactivities per molecule is preferable. The silane coupling agent is preferably a silane compound having at least one selected from a vinyl group, an epoxy group, a styryl group, a methacryl group, an amino group, an isocyanurate group, a ureido group, a mercapto group, a sulfide group, and an isocyanate group, and an alkoxy group. Specific examples of the silane coupling agent include N-P-aminoethyl-y-aminopropyl methyldimethoxysilane (KBM-602, manufactured by Shin-Etsu Chemical Co., Ltd.), N-β-aminoethyl-y-aminopropyl trimethoxysilane (KBM-603, manufactured by Shin-Etsu Chemical Co., Ltd.), N-β-aminoethyl-γ-aminopropyl triethoxysilane (KBE-602, manufactured by Shin-Etsu Chemical Co., Ltd.), γ-aminopropyl trimethoxysilane (KBM-903, manufactured by Shin-Etsu Chemical Co., Ltd.), γ-aminopropyl triethoxysilane (KBE-903, manufactured by Shin-Etsu Chemical Co., Ltd.), 3-methacryloxypropyl trimethoxysilane (KBM-503, manufactured by Shin-Etsu Chemical Co., Ltd.), and 3-glycidoxypropyl trimethoxysilane (KBM-403, manufactured by Shin-Etsu Chemical Co., Ltd.). With regard to details of the silane coupling agent, reference can be made to the descriptions in paragraph Nos. 0155 to 0158 of JP2013-254047A, the contents of which are incorporated herein by reference.

In a case where the photosensitive composition of the embodiment of the present invention includes a silane coupling agent, the content of the silane coupling agent is preferably 0.001% to 20% by mass, more preferably 0.01% to 10% by mass, and particularly preferably 0.1% by mass to 5% by mass, with respect to the total solid content of the photosensitive composition. The photosensitive composition of the embodiment of the present invention may include one kind or two or more kinds of the silane coupling agents. In a case where two or more kinds of the silane coupling agents are included, a total amount thereof preferably falls within the range.

### <<Polymerization Inhibitor>>

It is also preferable that to the photosensitive composition of the embodiment of the present invention contains a polymerization inhibitor. Examples of the polymerization inhibitor include hydroquinone, p-methoxyphenol, di-t-butyl-p-cresol, pyrogallol, t-butyl catechol, benzoquinone, 4,4′-thiobis (3-methyl-6-t-butylphenol), 2,2′-methylenebis(4-methyl-6-t-butylphenol), and an N-nitrosophenylhydroxylamine salt (an ammonium salt, a cerous salt, or the like).

In a case where the photosensitive composition of the embodiment of the present invention contains a polymerization inhibitor, the content of the polymerization inhibitor is preferably 0.01% to 5% by mass with respect to the total solid content of the photosensitive composition. The photosensitive composition of the embodiment of the present invention may include one kind or two or more kinds of the polymerization inhibitor. In a case where the photosensitive composition includes two or more kinds of the polymerization inhibitor, the total amount thereof is preferably within the range.

### <<Ultraviolet Absorber>>

The photosensitive composition of the embodiment of the present invention may contain an ultraviolet absorber. As the ultraviolet absorber, a conjugated diene-based compound is preferable. Examples of commercially available products of the ultraviolet absorber include UV-503 (manufactured by Daito Chemical Co., Ltd.). Further, as the ultraviolet absorber, an aminodiene compound, a salicylate compound, a benzophenone compound, a benzotriazole compound, an acrylonitrile compound, a triazine compound, or the like can be used. Specific examples thereof include the compounds described in JP2013-068814A. In addition, as the benzotriazole compound, MYUA series manufactured by Miyoshi Oil & Fat Co., Ltd. (The Chemical Daily, Feb. 1, 2016) may be used.

In a case where the photosensitive composition of the embodiment of the present invention contains an ultraviolet absorber, the content of the ultraviolet absorber is preferably 0.1% to 10% by mass, more preferably 0.1% to 5% by mass, and particularly preferably 0.1% to 3% by mass, with respect to the total solid content of the photosensitive composition. Further, only one kind or two or more kinds of the ultraviolet absorbers may be used. In a case where two or more kinds of the ultraviolet absorbers are included, the total amount thereof is preferably within the range.

### <<Other Additives>>

Various additives such as, for example, a filler, an adhesion promoter, an antioxidant, and an aggregation inhibitor can be blended into the photosensitive composition of the embodiment of the present invention, as desired. Examples of these additives include the additives described in paragraph Nos. 0155 and 0156 of JP2004-295116A, the contents of which are incorporated herein by reference. Further, as the antioxidant, for example, a phenol compound, a phosphorus-based compound (for example, the compounds described in paragraph No. 0042 of JP2011-090147A), a thioether compound, or the like can be used. Examples of a commercially available product of the antioxidant include ADEKA STAB series (AO-20, AO-30, AO-40, AO-50, AO-50F, AO-60, AO-60G, AO-80, AO-330, and the like), all of which are manufactured by ADEKA. Only one kind or two or more kinds of the antioxidants may be used as a mixture of two or more kinds thereof. The photosensitive composition of the embodiment of the present invention can contain the sensitizers or the light stabilizers described in paragraph No. 0078 of JP2004-295116A, or the thermal polymerization inhibitors described in paragraph No. 0081 of the same publication.

It is preferable that the photosensitive composition of the embodiment of the present invention substantially does not contain a black coloring agent and a chromatic coloring agent. In a case of substantially not containing a black coloring agent and a chromatic coloring agent, the total content of the black coloring agent and the chromatic coloring agent is preferably 0.1% by mass or less, and more preferably 0.05% by mass or less, with respect to the total solid content of the photosensitive composition, and still more preferably the black coloring agent and the chromatic coloring agent are not both contained. Further, the chromatic coloring agent as mentioned herein does not include the above-mentioned white series pigment.

### <Method for Preparing Photosensitive Composition>

The photosensitive composition of the embodiment of the present invention can be prepared by mixing the above-mentioned components. In the preparation of the photosensitive composition, the respective components may be blended at once, or the respective components may be dissolved and/or dispersed in a solvent, and then sequentially blended. Further, the order of the components to be introduced or the operational conditions during the blending is not particularly limited. For example, the photosensitive composition may be prepared by dissolving and/or dispersing all the components in a solvent at the same time, or by appropriately leaving the respective components in two or more solutions or dispersion liquids, and mixing them into a solution during the use (during the coating), as desired.

It is preferable that in the preparation of the photosensitive composition, a composition formed by mixing the respective components is filtered through a filter for the purpose of removing foreign matters, reducing defects, or the like. As the filter, any filters that have been used in the related art for filtration use and the like may be used without particular limitation. Examples of the filter include filters formed of materials including, for example, a fluorine resin such as polytetrafluoroethylene (PTFE), a polyamide-based resin such as nylon (for example, nylon-6 and nylon-6,6), and a polyolefin resin (including a polyolefin resin having a high density and/or an ultrahigh molecular weight) such as polyethylene and polypropylene (PP). Among these materials, polypropylene (including a high-density polypropylene) and nylon are preferable.

The pore diameter of the filter is suitably approximately 0.01 to 7.0 μm, preferably approximately 0.01 to 3.0 μm, and more preferably approximately 0.05 to 0.5 μm.

In addition, it is also preferable that a filter using a fibrous filter material is used as the filter. Examples of the fibrous filter material include a polypropylene fiber, a nylon fiber, and a glass fiber. Examples of a filter using the fibrous filter material include filter cartridges of SBP type series (SBP008 and the like), TPR type series (TPR002, TPR005, and the like), or SHPX type series (SHPX003 and the like), manufactured by Roki Techno Co., Ltd.

In a case of using a filter, different filters may be combined. Here, the filtration with each of the filters may be run once or may be repeated twice or more times.

For example, filters having different pore diameters within the above-mentioned range may be combined. With regard to the pore diameter of the filter herein, reference can be made to nominal values of filter manufacturers. A commercially available filter may be selected from, for example, various filters provided by Nihon Pall Corporation (DFA4201NXEY and the like), Toyo Roshi Kaisha., Ltd., Nihon Entegris K. K. (formerly Nippon Microlith Co., Ltd.), Kitz Micro Filter Corporation, and the like.

In addition, the filtration through the first filter may be performed with only a dispersion liquid, the other components may be mixed therewith, and then the filtration through the second filter may be performed. As the second filter, a filter formed of the same material as that of the first filter, or the like can be used.

The photosensitive composition of the embodiment of the present invention can be used after its viscosity is adjusted for the purposes of adjusting the state of a film surface (flatness or the like), adjusting a film thickness, or the like. The value of the viscosity can be appropriately selected as desired, and is, for example, preferably 0.3 mPa·s to 50 mPa·s, and more preferably 0.5 mPa·s to 20 mPa·s at 25° C. As for a method for measuring the viscosity, the viscosity can be measured, for example, with a temperature being adjusted to 25° C., using a viscometer RE85L (rotor: 1°34′×R24, measurement range of 0.6 to 1,200 mPa·s) manufactured by Toki Sangyo Co., Ltd.

The moisture content in the photosensitive composition of the embodiment of the present invention is usually 3% by mass or less, preferably 0.01% to 1.5% by mass, and more preferably in the range of 0.1% to 1.0% by mass. The moisture content can be measured by a Karl Fischer method.

### <Applications of Photosensitive Composition>

The photosensitive composition of the embodiment of the present is suitably used for foie ling white pixels in a color filter. Further, the photosensitive composition of the embodiment of the present invention can be used in a color filter or the like in a solid-state imaging element such as a charge-coupled device (CCD) and a complementary metal-oxide semiconductor (CMOS), or an image display device such as a liquid crystal display device.

### <Cured Film>

The cured film of an embodiment of the present invention is a cured film formed by curing the above-mentioned the photosensitive composition of the embodiment of the present invention. The thickness of the cured film is preferably 0.1 to 2.0 μm. The lower limit is preferably 0.2 μm or more, and more preferably 0.3 μm or more. The upper limit is preferably 1.7 μm or less, and more preferably 1.5 μm or less.

The cured film of the embodiment of the present invention has a transmittance across the entire wavelength range of light at 400 nm to 700 nm of preferably 85% or more, more preferably 88% or more, still more preferably 89% or more, and particularly preferably 90% or more. According to this aspect, the cured film has characteristics that are preferable as white pixels in a color filter.

### <Color Filter>

Next, the color filter of an embodiment of the present invention will be described. The color filter of the embodiment of the present invention has the above-mentioned cured film of the embodiment of the present invention. That is, the color filter of the embodiment of the present invention may have at least a transparent (white) pattern (white pixels) which is from pixels formed using the photosensitive composition of the embodiment of the present invention.

Examples of embodiments of specific forms of the color filter of the embodiment of the present invention include a form of a multi-color color filter with a combination of white pixels and other colored pixels (for example, a color filter in four or more colors, which has at least white pixels, red pixels, blue pixels, and green pixels).

The film thickness of the white pixel in the color filter is preferably 0.1 to 2.0 μm. The lower limit is preferably 0.2 μm or more, and more preferably 0.3 μm or more. The upper limit is preferably 1.7 μm or less, and more preferably 1.5 μm or less.

The width of the white pixel in the color filter is preferably 0.5 to 20.0 μm. The lower limit is preferably 1.0 μm or more, and more preferably 2.0 μm or more. The upper limit is preferably 15.0 μm or less, and more preferably 10.0 μm or less.

The color filter of the embodiment of the present invention can be used for a solid-state imaging element such as a charge-coupled device (CCD) and a complementary metal-oxide semiconductor (CMOS), an image display device, or the like.

In a case where the photosensitive composition of the embodiment of the present invention is used as a color filter in applications for a liquid crystal display device, the voltage holding ratio of a liquid crystal display element comprising a color filter is preferably 70% or more, and more preferably 90% or more. Known means for obtaining a high voltage holding ratio can be incorporated as appropriate, and examples of typical means include a use of high-purity materials (for example, reduction in ionic impurities) and a control of the amount of acidic functional groups in a composition. The voltage holding ratio can be measured by, for example, the methods described in paragraph No. 0243 of JP2011-008004A or paragraph Nos. 0123 to 0129 of JP2012-224847A, or the like.

### <Pattern Forming Method>

The pattern forming method of an embodiment of the present invention includes:
a step of forming a photosensitive composition layer on a support using the photosensitive composition of the embodiment of the present invention,
a step of patternwise exposing the photosensitive composition layer by irradiation with light at a wavelength of more than 350 nm and 380 nm or less,
a step of developing the photosensitive composition layer after the exposure, and
a step of exposing the photosensitive composition layer after the development by irradiation with light at a wavelength of 254 to 350 nm. Incidentally, a step of baking the photosensitive composition layer after being formed on a support and before exposure (pre-baking step) and a step of baking the developed pattern (post-baking step) may be provided, as desired. Hereinafter, the respective steps will be described.

In the step of forming a photosensitive composition layer, a photosensitive composition layer is formed on a support, using the photosensitive composition.

The support is not particularly limited and can be appropriately selected depending on applications. Examples of the support include a glass substrate, a substrate for a solid-state imaging element, on which a solid-state imaging element (light-receiving element) such as a CCD and a CMOS is provided, and a silicon substrate. Further, an undercoat layer may be provided on the support, as desired, so as to improve adhesion to a layer above the support, to prevent diffusion of materials, or to flatten a surface of the substrate.

As a method for applying the photosensitive composition onto the support, various coating methods such as slit coating, an ink jet method, rotation coating, cast coating, roll coating, and a screen printing method can be used.

The photosensitive composition layer formed on the support may be dried (pre-baked). In a case of forming a pattern by a low-temperature process, pre-baking may not be performed. In a case of performing the pre-baking, the pre-baking temperature is preferably 120° C. or lower, more preferably 110° C. or lower, and still more preferably 105° C. or lower. The lower limit may be set to, for example, 50° C. or higher, or to 80° C. or higher. The pre-baking time is preferably 10 seconds to 300 seconds, more preferably 40 to 250 seconds, and still more preferably 80 to 220 seconds. The pre-baking can be performed using a hot plate, an oven, or the like.

Next, the photosensitive composition layer is patternwise exposed by irradiation with light at a wavelength of more than 350 to 380 nm or less. For example, the photosensitive composition layer can be subjected to patternwise exposure by performing exposure using an exposure device such as a stepper through a mask having a predetermined mask pattern. Thus, the exposed portion can be cured. The radiation (light) which can be used during the exposure is light at a wavelength of more than 350 nm and 380 nm or less, preferably light at a wavelength of 355 to 370 nm, and more preferably i-rays. The irradiation amount (exposure dose) is preferably 30 to 1,500 mJ/cm², and more preferably 50 to 1,000 mJ/cm². The oxygen concentration during the exposure can be appropriately selected, and the exposure may also be performed, for example, in a low-oxygen atmosphere having an oxygen concentration of 19% by volume or less (for example, 15% by volume, 5% by volume, and substantially oxygen-free) or in a high-oxygen atmosphere having an oxygen concentration of more than 21% by volume (for example, 22% by volume, 30% by volume, and 50% by volume), in addition to air. Further, the exposure illuminance can be appropriately set, and can be usually selected from a range of 1,000 W/m² to 100,000 W/m² (for example, 5,000 W/m², 15,000 W/m², or 35,000 W/m²). Appropriate conditions of each of the oxygen concentration and the illuminance of exposure energy may be combined, and for example, a combination of the oxygen concentration of 10% by volume and the illuminance of 10,000 W/m², a combination of the oxygen concentration of 35% by volume and the illuminance of 20,000 W/m², or the like is available.

The reaction rate of the polymerizable compound in the photosensitive composition layer after the exposure is preferably more than 30% and less than 60%. With such a reaction rate, the polymerizable compound can be in the state of being appropriately cured. Here, the reaction rate of the polymerizable compound refers to a proportion of the reacted ethylenically unsaturated double bonds in all the ethylenically unsaturated double bonds contained in the polymerizable compound.

Next, the photosensitive composition layer after the exposure is developed. That is, the photosensitive composition layer in the unexposed areas is removed by development to form a pattern. The removal of the photosensitive composition layer in the unexposed areas by development can be performed using a developer. As the developer, an organic alkali developer causing no damage on the underlying solid-state imaging element, circuit, or the like is preferable. The temperature of the developer is, for example, preferably 20° C. to 30° C., and the development time is preferably 20 to 300 seconds.

As the developer, an aqueous alkaline solution obtained by diluting an alkali agent with pure water is preferably used. Examples of the alkali agent include organic alkaline compounds such as aqueous ammonia, ethylamine, diethylamine, dimethylethanolamine, diglycol amine, diethanolamine, hydroxyamine, ethylenediamine, tetramethylammonium hydroxide, tetraethyl ammonium hydroxide, tetrapropyl ammonium hydroxide, tetrabutylammonium hydroxide, benzyltrimethylammonium hydroxide, dimethylbis(2-hydroxyethyl)ammonium hydroxide, choline, pyrrole, piperidine, and 1,8-diazabicyclo[5.4.0]-7-undecene, and inorganic alkaline compounds such as sodium hydroxide, potassium hydroxide, sodium carbonate, sodium hydrogen carbonate, sodium silicate, and sodium metasilicate. The concentration of the alkali agent in the aqueous alkaline solution is preferably 0.001% to 10% by mass, and more preferably 0.01% to 1% by mass. Moreover, the developer may further include a surfactant. Examples of the surfactant include the surfactants described as the above-mentioned photosensitive composition, and the surfactant is preferably a nonionic surfactant.

In addition, in a case where a developer including such an aqueous alkaline solution is used, it is preferable to perform washing (rinsing) with pure water after development.

Next, the photosensitive composition layer after developing was exposed by irradiation with light at a wavelength of 254 to 350 nm. Hereinafter, the exposure after development is also referred to second exposure.

As a radiation (light) that can be used during the second exposure, ultraviolet rays at a wavelength of 254 to 300 nm are preferable, and ultraviolet rays at a wavelength of 254 nm are more preferable. The second exposure can be performed using, for example, an ultraviolet photoresist curing device. From the ultraviolet photoresist curing device, for example, light at a wavelength of 254 to 350 nm and other lights (for example, i-rays) may be irradiated.

A difference between the wavelength of light used for exposure before development as described above and the wavelength of light used for exposure after development (second exposure) is preferably 200 nm or less, and more preferably 100 to 150 nm.

The irradiation dose (exposure dose) is preferably 30 to 4,000 mJ/cm², and more preferably 50 to 3,500 mJ/cm². The oxygen concentration during exposure can be appropriately selected. The conditions described in the exposing step before development as described above may be mentioned herein.

The reaction rate of the polymerizable compound in the photosensitive composition layer after the second exposure is preferably 60% or more. The upper limit can be set to 100% or less or to 90% or less. By adopting such a reaction rate, the cured state of the photosensitive composition layer after the exposure can be improved.

In the present invention, by exposing the photosensitive composition layer in two steps before and after development, the photosensitive composition can be appropriately cured in the first exposure (exposure before development), and the entire photosensitive composition can be appropriately completely cured in the next exposure (exposure after development). As a result, the curability of the photosensitive composition can be improved even under the condition of a low temperature, and a pattern having excellent solvent resistance (cured film) can be formed.

In the formation of the pattern formation of the present invention, post-baking after the second exposure may further be performed. In a case of performing post-baking, using an organic electroluminescence element as a light emitting source of an image display device, or a case of constituting a photoelectric conversion film of an image sensor with organic materials, it is preferable to perform a heating treatment (post-baking) at 50° C. to 120° C. (more preferably 80° C. to 100° C., and still more preferably 80° C. to 90° C.). The post-baking can be performed continuously or batchwise using a heating unit such as a hot plate, a convection oven (hot-air circulating dryer), and a high-frequency heater. In addition, in a case of forming a pattern by a low-temperature process, the post-baking may not be carried out.

The thickness of the pattern (hereinafter also referred to as pixels) after the second exposure (after post-baking in a case where the post-baking is performed after the second exposure) is preferably 0.1 to 2.0 μm. The lower limit is preferably 0.2 μm or more, and more preferably 0.3 μm or more. The upper limit is preferably 1.7 μm or less, and more preferably 1.5 μm or less.

The width of the pixel is preferably 0.5 to 20.0 μm. The lower limit is preferably 1.0 μm or more, and more preferably 2.0 μm or more. The upper limit is preferably 15.0 μm or less, and more preferably 10.0 μm or less.

The Young's modulus of the pixel is preferably 0.5 to 20 GPa, and more preferably 2.5 to 15 GPa.

The pixels preferably have high flatness. Specifically, the surface roughness Ra of the pixels is preferably 100 nm or less, more preferably 40 nm or less, and still more preferably 15 nm or less. The lower limit is not specified, it is, for example, preferably 0.1 nm or more. The surface roughness can be measured, for example, using an atomic force microscope (AFM) Dimension 3100 manufactured by Veeco Instruments, Inc.

In addition, the contact angle of water on the cured film can be appropriately set to a preferred value, but is typically in the range of 50° to 110° . The contact angle can be measured, for example, using a contact angle meter CV-DT·A Model (manufactured by Kyowa Interface Science Co., Ltd.).

A higher volume resistivity value of the pixels is desired. Specifically, the volume resistivity value of the pixels is preferably 10⁹ Ω·cm or more, and more preferably 10¹¹ Ω·cm or more. The upper limit is not specified, but is, for example, preferably 10¹⁴ Ω·cm or less. The volume resistivity value of the pixel can be measured, for example, using an ultra high resistance meter 5410 (manufactured by Advantest Corporation).

### <Solid-State Imaging Element>

The solid-state imaging element of an embodiment of the present invention has the above-mentioned cured film of the embodiment of the present invention. The configuration of the solid-state imaging element of the embodiment of the present invention is not particularly limited as long as the solid-state imaging element is configured to include the cured film in the embodiment of the present invention and function as a solid-state imaging element. However, examples thereof include the following configurations.

The solid-state imaging element is configured to have a plurality of photodiodes constituting a light receiving area of the solid-state imaging element (a charge coupled device (CCD) image sensor, a complementary metal-oxide semiconductor (CMOS) image sensor, or the like), and a transfer electrode formed of polysilicon or the like on a substrate; have a light-shielding film having openings only over the light receiving portion of the photodiode, on the photodiodes and the transfer electrodes; have a device-protective film formed of silicon nitride or the like, which is formed to coat the entire surface of the light-shielding film and the light receiving portion of the photodiodes, on the light-shielding film; and have a color filter on the device-protective film. In addition, the solid-state imaging element may also be configured, for example, such that it has a light collecting means (for example, a microlens, which is the same hereinafter) on a device-protective film under a color filter (a side closer to the substrate), or has a light collecting means on a color filter. Further, the color filter may have a structure in which a cured film forming each pixel is embedded in, for example, a space partitioned in a lattice shape by a partition wall. The partition wall in this case preferably has a low refractive index for each pixel. Examples of an imaging device having such a structure include the devices described in JP2012-227478A and JP2014-179577A. An imaging device comprising the solid-state imaging element of the embodiment of the present invention can also be used as a vehicle camera or a monitoring camera, in addition to a digital camera or electronic equipment (mobile phones or the like) having an imaging function.

### <Image Display Device>

The cured film of the embodiment of the present invention can be used for an image display device such as a liquid crystal display device and an organic electroluminescence display device. The definitions of image display devices or the details of the respective image display devices are described in, for example, “Electronic Display Device (Akio Sasaki, Kogyo Chosakai Publishing Co., Ltd., published in 1990)”, “Display Device (Sumiaki Ibuki, Sangyo Tosho Co., Ltd., published in 1989)”, and the like. In addition, the liquid crystal display device is described in, for example, “Liquid Crystal Display Technology for Next Generation (edited by Tatsuo Uchida, Kogyo Chosakai Publishing Co., Ltd., published in 1994)”. The liquid crystal display device to which the present invention can be applied is not particularly limited, and can be applied to, for example, liquid crystal display devices employing various systems described in the “Liquid Crystal Display Technology for Next Generation”.

### EXAMPLES

Hereinbelow, the present invention will be described in more detail with reference to Examples. The materials, the amounts of materials used, the proportions, the treatment details, the treatment procedure, or the like shown in the Examples below may be modified if appropriate as long as the modifications do not depart from the spirit of the present invention. Therefore, the scope of the present invention should not be construed as being limited to the specific Examples set forth below. In addition, “parts” and “%” are on a mass basis unless otherwise specified.

### <Preparation of Pigment Dispersion Liquid 1>

A mixed solution with the following composition was subjected to a dispersion treatment using ULTRA APEX MILL (trade name) manufactured by Kotobuki Industries Co., Ltd. as a circulation type dispersing device (beads mill) to obtain a pigment dispersion liquid 1.

### (Composition A)

White pigment (particles obtained by subjecting the surface of particles of titanium dioxide with a surface treatment agent including aluminum hydroxide (Al(OH)₃) and amorphous silicic acid (SiO₂) and stearic acid (C₁₇H₃₅COOH) (containing of titanium dioxide in an amount of 75% by mass or more, aluminum hydroxide in an amount of less than 15% by mass, amorphous silica in an amount of less than 5% by mass, and stearic acid of less than 10% by mass), and average primary particle diameter of 40 nm) . . . 22.8 parts by mass
Dispersant (a resin having the following structure, an acid value=50 mgKOH/g, a weight-average molecular weight=10,000, the numerical values appended to the main chains are molar ratios, and the numerical values appended to side chains are the number of repeating units) . . . 6.1 parts by mass

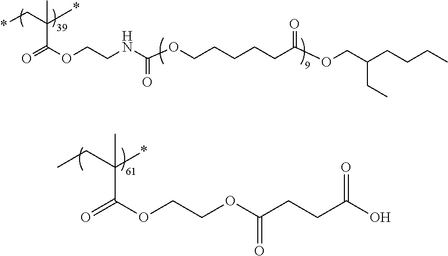

Propylene glycol monomethyl ether acetate (PGMEA) 71.1 parts by mass

The dispersing device was operated under the following conditions.
Bead diameter: Diameter of 0.05 mm
Bead filling ratio: 75% by volume
Circumferential speed: 8 m/sec
Pump supply amount: 10 Kg/hour
Cooling water: Tap water
Inner volume of beads mill annular passage: 0.15 L
Amount of mixed solution to be subjected to dispersion treatment: 0.44 kg

### <Preparation of Photosensitive Composition>

The raw materials shown in Tables 1 to 3 were mixed at the ratios (parts by mass) shown in Tables 1 to 3, stirred, and then filtered with a nylon-made filter having a pore diameter of 0.45 μm (manufactured by Nihon Pall Ltd.) to prepare a photosensitive composition.

TABLE 1

| | | Example | Example | Example | Example | Example | Example | Example | Example | Example | Example |
|---|---|---|---|---|---|---|---|---|---|---|---|
| | | 1 | 2 | 3 | 4 | 5 | 6 | 7 | 8 | 9 | 10 |
| Pigment dispersion liquid 1 | | 38.5 | 38.5 | 38.5 | 38.5 | 38.5 | 38.5 | 38.5 | 38.5 | 38.5 | 38.5 |
| Alkali-soluble resin | P-1 | 2.44 | 2.44 | 2.44 | 2.44 | 2.44 | 2.44 | 2.44 | 2.44 | 2.44 | 2.44 |
| | P-2 | | | | | | | | | | |
| | P-3 | | | | | | | | | | |
| Polymerizable | M-1 | 4.3 | 4.3 | 4.3 | 4.3 | 4.3 | 4.3 | 4.3 | 4.3 | 4.3 | 4.3 |
| compound | | | | | | | | | | | |
| Photopolymerization | D1-1 | 1.38 | 1.23 | 1.12 | 0.92 | 0.77 | 0.61 | | | 1.12 | |
| initiator D1 | D1-2 | | | | | | | 1.12 | | | 1.12 |
| | D1-3 | | | | | | | | 1.12 | | |
| Photopolymerization | D2-1 | 0.15 | 0.31 | 0.41 | 0.61 | 0.76 | 0.92 | 0.41 | 0.41 | | |
| initiator D2 | D2-2 | | | | | | | | | 0.41 | 0.41 |
| | D2-3 | | | | | | | | | | |
| Photopolymerization | D3-1 | | | | | | | | | | |
| initiator D3 | | | | | | | | | | | |

| | | | | | | | | | | |
|---|---|---|---|---|---|---|---|---|---|---|
| Polymerization inhibitor 1 | 0.002 | 0.002 | 0.002 | 0.002 | 0.002 | 0.002 | 0.002 | 0.002 | 0.002 | 0.002 |
| Surfactant 1 | 0.025 | 0.025 | 0.025 | 0.025 | 0.025 | 0.025 | 0.025 | 0.025 | 0.025 | 0.025 |
| Organic solvent 1 | 49.18 | 49.18 | 49.18 | 49.18 | 49.18 | 49.18 | 29.18 | 49.18 | 49.18 | 49.18 |
| Organic solvent 2 | 4.02 | 4.02 | 4.02 | | 4.02 | 4.02 | 4.02 | 4.02 | 4.02 | 4.02 |
| Organic solvent 3 | | | | 4.02 | | | 20 | | | |
| Mass ratio of D1 to D2 | 90:10 | 80:20 | 73:27 | 60:40 | 50:50 | 40:60 | 73:27 | 73:27 | 73:27 | 73:27 |
| Content (% by mass) of | 7.78 | 7.78 | 7.78 | 7.78 | 7.78 | 7.78 | 7.78 | 7.78 | 7.78 | 7.78 |
| photopolymerization initiator | | | | | | | | | | |
| in total solid content | | | | | | | | | | |

TABLE 2

| | | Example | Example | Example | Example | Example | Example | Example | Example | Example | Example |
|---|---|---|---|---|---|---|---|---|---|---|---|
| | | 11 | 12 | 13 | 14 | 15 | 16 | 17 | 18 | 19 | 20 |
| Pigment dispersion liquid 1 | | 38.5 | 38.5 | 38.5 | 38.5 | 38.5 | 38.5 | 38.5 | 38.5 | 38.5 | 38.5 |
| Alkali-soluble resin | P-1 | 2.44 | 2.44 | 2.44 | 2.44 | 2.9 | 3.36 | 1.98 | 1.52 | | |
| | P-2 | | | | | | | | | 2.44 | |
| | P-3 | | | | | | | | | | 2.44 |
| Polymerizable | M-1 | 4.3 | 4.3 | 4.3 | 4.3 | 4.3 | 4.3 | 4.3 | 4.3 | 4.3 | 4.3 |
| compound | | | | | | | | | | | |
| Photopolymerization | D1-1 | | 1.12 | | | 0.78 | 0.45 | 1.46 | 1.79 | 1.12 | 1.12 |
| initiator D1 | D1-2 | | | 1.12 | | | | | | | |
| | D1-3 | 1.12 | | | 1.12 | | | | | | |
| Photopolymerization | D2-1 | | | | | 0.29 | 0.17 | 0.54 | 0.66 | 0.41 | 0.41 |
| initiator D2 | D2-2 | 0.41 | | | | | | | | | |
| | D2-3 | | 0.41 | 0.41 | 0.41 | | | | | | |
| Photopolymerization | D3-1 | | | | | | | | | | |
| initiator D3 | | | | | | | | | | | |

| | | | | | | | | | | |
|---|---|---|---|---|---|---|---|---|---|---|
| Polymerization inhibitor 1 | 0.002 | 0.002 | 0.002 | 0.002 | 0.002 | 0.002 | 0.002 | 0.002 | 0.002 | 0.002 |
| Surfactant 1 | 0.025 | 0.025 | 0.025 | 0.025 | 0.025 | 0.025 | 0.025 | 0.025 | 0.025 | 0.025 |
| Organic solvent 1 | 49.18 | 49.18 | 49.18 | 49.18 | 49.18 | 49.18 | 49.18 | 49.18 | 49.18 | 49.18 |
| Organic solvent 2 | 4.02 | 4.02 | 4.02 | 4.02 | 4.02 | 4.02 | 4.02 | 4.02 | 4.02 | 4.02 |
| Mass ratio of D1 to D2 | 73:27 | 73:27 | 73:27 | 73:27 | 73:27 | 73:27 | 73:27 | 73:27 | 73:27 | 73:27 |
| Content (% by mass) of | 7.78 | 7.78 | 7.78 | 7.78 | 5.52 | 3.15 | 10.24 | 12.61 | 7.88 | 7.88 |
| photopolymerization initiator | | | | | | | | | | |
| in total solid content | | | | | | | | | | |

TABLE 3

| | | Comparative | Comparative | Comparative | Comparative | Comparative |
|---|---|---|---|---|---|---|
| | | Example 1 | Example 2 | Example 3 | Example 4 | Example 5 |
| Pigment dispersion liquid 1 | | 38.5 | 38.5 | 38.5 | 38.5 | 38.5 |
| Alkali-soluble resin | P-1 | 2.44 | 2.44 | 2.44 | 2.44 | 2.44 |
| | P-2 | | | | | |
| | P-3 | | | | | |
| Polymerizable | M-1 | 4.3 | 4.3 | 4.3 | 4.3 | 4.3 |
| compound | | | | | | |
| Photopolymerization | D1-1 | 1.53 | 0.46 | | 1.12 | |
| initiator D1 | D1-2 | | | | | |
| | D1-3 | | | | | |
| Photopolymerization | D2-1 | | 1.07 | 1.53 | | 0.41 |
| initiator D2 | D2-2 | | | | | |
| | D2-3 | | | | | |
| Photopolymerization | D3-1 | | | | 0.41 | 1.12 |
| initiator D3 | | | | | | |

| | | | | | |
|---|---|---|---|---|---|
| Polymerization inhibitor 1 | 0.002 | 0.002 | 0.002 | 0.002 | 0.002 |
| Surfactant 1 | 0.025 | 0.025 | 0.025 | 0.025 | 0.025 |
| Organic solvent 1 | 49.18 | 49.18 | 49.18 | 49.18 | 49.18 |
| Organic solvent 2 | 4.02 | 4.02 | 4.02 | 4.02 | 4.02 |
| Mass ratio of D1 to D2 | 100:0 | 30:70 | 0:100 | — | — |
| Content (% by mass) of | 7.88 | 7.88 | 7.88 | 7.88 | 7.88 |
| photopolymerization initiator | | | | | |
| in total solid content | | | | | |

The raw materials described in the tables are as follows. Further, the mass ratio of D1 and D2 in the tables are the mass ratio of the photopolymerization initiator D1 to the photopolymerization initiator D2 (photopolymerization initiator D1:photopolymerization initiator D2).

(Pigment Dispersion Liquid)
Pigment dispersion liquid 1: Pigment dispersion liquid 1 mentioned above (Alkali-Soluble Resin)
P-1: Resin having the following structure (an acid value=79.3 mgKOH/g, a hydroxyl number=71.7 mgKOH/g, a weight-average molecular weight=14,000, and the numerical values appended to the main chains are molar ratios)
P-2: Resin having the following structure (an acid value=73.1 mgKOH/g, a hydroxyl number=36.6 mgKOH/g, a weight-average molecular weight=14,000, and the numerical values appended to the main chains are molar ratios)
P-3: Resin having the following structure (an acid value=112.8 mgKOH/g, a hydroxyl number=0 mgKOH/g, a weight-average molecular weight=30,000, and the numerical values shown together with the main chains are molar ratios)

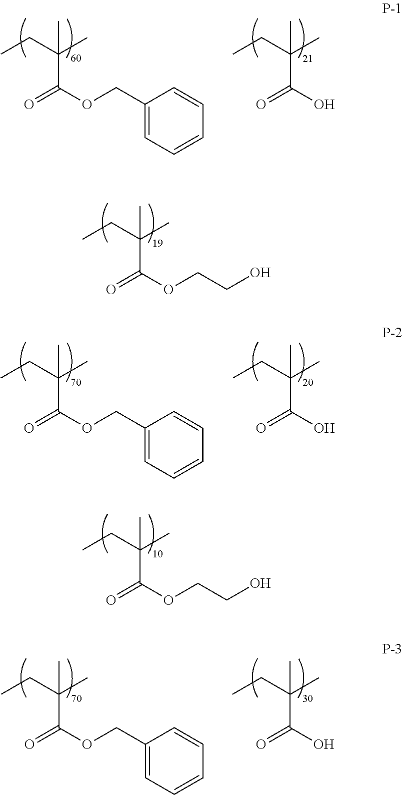

(Polymerizable Compound)
M-1: Mixture of the following compounds (a mixture with a molar ratio of the molar ratio of the left compound to the right compound of 7:3)

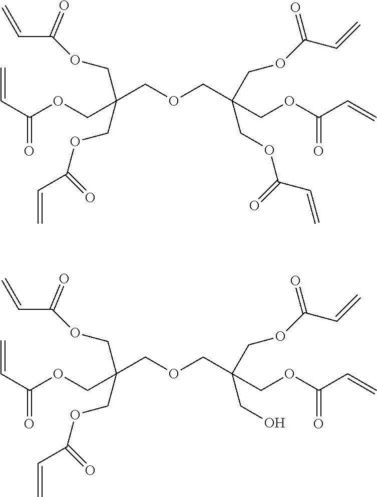

(Photopolymerization initiator D1 : Photopolymerization initiator having a light absorption coefficient of 1.0×10³ mL/gcm or more at a wavelength of 365 nm in methanol)
D1-1: IRGACURE-OXE01 (manufactured by BASF, a compound having the following structure, and a light absorption coefficient of 6,969 mL/gcm at a wavelength of 365 nm in methanol)
D1-2: IRGACURE-OXE02 (manufactured by BASF, a compound having the following structure, and a light absorption coefficient of 7,749 mL/gcm at a wavelength of 365 nm in methanol)
D1-3: IRGACURE-819 (manufactured by BASF, a compound having the following structure, and a light absorption coefficient of 2,309 mL/gcm at a wavelength of 365 nm in methanol)

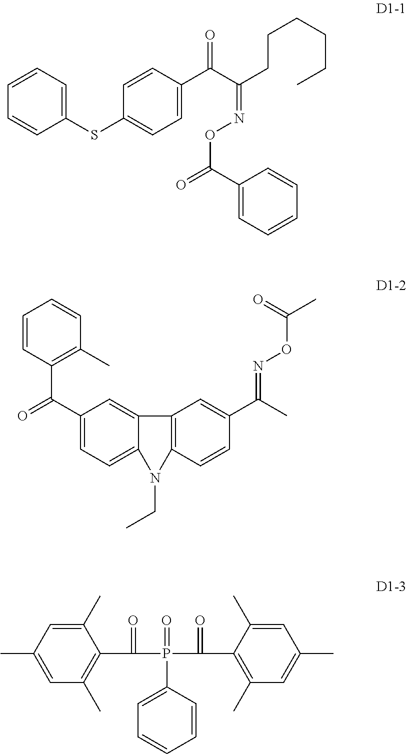

(Photopolymerization initiator D2: Photopolymerization initiator having a light absorption coefficient of 1.0×10² mL/gcm or less at a wavelength of 365 nm in methanol and a light absorption coefficient of 1.0×10³ mL/gcm or more at a wavelength of 254 nm)
D2-1: IRGACURE-2959 (manufactured by BASF, a compound having the following structure, a light absorption coefficient of 48.93 mL/gcm at a wavelength of 365 nm in methanol, and a light absorption coefficient of 3.0×10⁴ mL/gcm at a wavelength of 254 nm)
D2-2: IRGACURE-184 (manufactured by BASF, a compound having the following structure, a light absorption coefficient of 88.64 mL/gcm at a wavelength of 365 nm in methanol, and a light absorption coefficient of 3.3×10⁴ mL/gcm at a wavelength of 254 nm)
D2-3: DAROCUR-MBF (manufactured by BASF, a compound having the following structure, a light absorption coefficient of 38 mL/gcm at a wavelength of 365 nm in methanol, and a light absorption coefficient of 9.2×10⁴ mL/gcm at a wavelength of 254 nm)

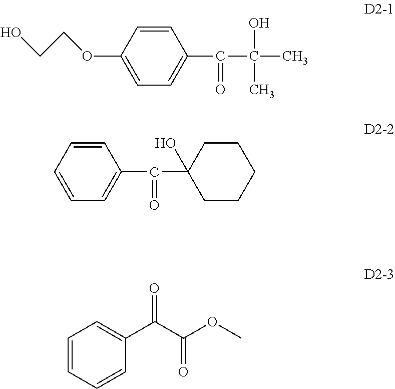 [SMILES: CC(C)(O)C(=O)c1ccc(OCCO)cc1 ; O=C(c1ccccc1)C1(O)CCCCC1 ; COC(=O)C(=O)c1ccccc1]

(Photopolymerization initiator D3: Photopolymerization initiator not corresponding to any of photopolymerization initiator D1 and photopolymerization initiator D2)
D3-1: IRGACURE-907 (manufactured by BASF, a compound having the following structure, a light absorption coefficient of 466.5 mL/gcm at a wavelength of 365 nm in methanol, and a light absorption coefficient of 3.9×10³ mL/gcm at a wavelength of 254 nm in methanol)

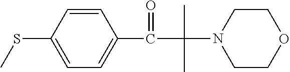 [SMILES: CSc1ccc(C(=O)C(C)(C)N2CCOCC2)cc1]

(Other Components)
Polymerization inhibitor 1: p-Methoxyphenol
Organic solvent 1: Propylene glycol methyl ether acetate
Organic solvent 2: Cyclohexanone
Organic solvent 3: Propylene glycol methyl ether
Surfactant 1: The following mixture (a weight-average molecular weight=14,000).
   In the following formulae, % representing the proportion of the repeating units is % by mass.

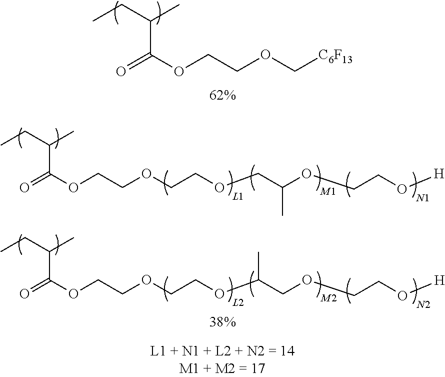

### <Evaluation of Rectangularity>

The photosensitive composition was applied onto a silicon wafer by a spin coating method such that the film thickness after coating became 0.5 μm, and then subjected to a heating treatment using a hot plate at 100° C. for 120 seconds to form a photosensitive composition layer. Next, exposure was performed through a mask having an island pattern in 10 μm×10 μm formed therein with i-rays at an exposure dose of 100 mJ/cm², using an i-ray stepper exposure device. Thereafter, puddle development at 23° C. for 60 seconds as performed using a 0.3%-by-mass aqueous tetramethylammonium hydroxide solution, and then a rinsing treatment was performed. Subsequently, exposure was performed (second exposure) with light at a wavelength of 254 to 350 nm at an exposure dose of 3,000 mJ/cm² to form a pattern (negative image of the mask).

From the side above the silicon wafer, the width of the pattern formed on the silicon wafer and the length of the diagonal line of the pattern were observed using a critical dimension-scanning electron microscope (SEM). The rectangularity was evaluated according to the following standard. As the value of the length of the diagonal line of the pattern/(the width of the pattern×2^{0.5}) is closer to 10, the rectangularity is better.
5: The length of the diagonal line of the pattern/(the width of the pattern×2^{0.5}) is more than 0.95 and 1.0 or less.
4: The length of the diagonal line of the pattern/(the width of the pattern×2^{0.5}) is more than 0.90 and 0.95 or less.
3: The length of the diagonal line of the pattern/(the width of the pattern×2^{0.5}) is more than 0.85 and 0.90 or less.
2: The length of the diagonal line of the pattern/(the width of the pattern×2^{0.5}) is more than 0.75 and 0.85 or less.
1: The length of the diagonal line of the pattern/(the width of the pattern×2^{0.5}) is 0.75 or less.

### <Evaluation of Solvent Resistance>

The photosensitive composition was applied onto a silicon wafer by a spin coating method such that the film thickness after coating became 0.5 μm, and then subjected to a heating treatment using a hot plate at 100° C. for 120 seconds to form a photosensitive composition layer. Next, i-rays were irradiated at an exposure dose of 100 mJ/cm² using an i-ray stepper exposure device. Subsequently, exposure was performed (second exposure) with light at a wavelength of 254 to 350 nm at an exposure dose of 3,000 mJ/cm² using an ultraviolet photocuring device to produce a cured film.

N-methylpyrrolidone (NMP) was added dropwise to the obtained cured film, left to stand for 200 seconds, and then rinsed for 10 seconds using flowing water to perform a solvent resistance test. The thickness of each of the cured films before and after the solvent resistance test was measured and the residual film rate was measured to evaluate the solvent resistance. As the residual film rate is closer to 1, the solvent resistance is more excellent.

Residual film rate=Thickness of the cured film after the solvent resistance test/thickness of the cured film before the solvent resistance test
5: The residual film rate is 0.95 or more and 1.0 or less.
4: The residual film rate is 0.9 or more and less than 0.95.
3: The residual film rate is 0.85 or more and less than 0.9.
2: The residual film rate is 0.8 or more and less than 0.85.
1: The residual film rate is less than 0.8.

TABLE 4

| | Rectangularity | Solvent resistance |
|---|---|---|
| Example 1 | 3 | 3 |
| Example 2 | 4 | 4 |
| Example 3 | 5 | 5 |
| Example 4 | 4 | 5 |
| Example 5 | 3 | 5 |
| Example 6 | 3 | 4 |
| Example 7 | 4 | 5 |
| Example 8 | 3 | 5 |
| Example 9 | 5 | 4 |
| Example 10 | 4 | 4 |
| Example 11 | 3 | 4 |
| Example 12 | 3 | 4 |
| Example 13 | 5 | 3 |
| Example 14 | 4 | 3 |
| Example 15 | 4 | 4 |
| Example 16 | 3 | 3 |
| Example 17 | 4 | 5 |
| Example 18 | 3 | 5 |
| Example 19 | 4 | 5 |
| Example 20 | 3 | 5 |
| Comparative Example 1 | 1 | 1 |
| Comparative Example 2 | 2 | 3 |
| Comparative Example 3 | 1 | 2 |
| Comparative Example 4 | 3 | 2 |
| Comparative Example 5 | 2 | 3 |

As shown in the above table, in Examples, it was possible to form a pattern having excellent rectangularity and solvent resistance. On the other hand, in Comparative Examples, at least one of the rectangularity or the solvent resistance was deteriorated, as compared with Examples.

What is claimed is:

1. A photosensitive composition comprising:
a white or colorless pigment A;
an alkali-soluble resin B;
a polymerizable compound C having an ethylenically unsaturated double bond;
a photopolymerization initiator D1 having a light absorption coefficient of 1.0×10³ mL/gcm or more at a wavelength of 365 nm in methanol; and
a photopolymerization initiator D2 having a light absorption coefficient of 1.0×10² mL/gcm or less at a wavelength of 365 nm in methanol and a light absorption coefficient of 1.0×10³ mL/gcm or more at a wavelength of 254 nm,
wherein the mass ratio of the photopolymerization initiator D1 to the photopolymerization initiator D2 is photopolymerization initiator D1 :photopolymerization initiator D2=90:10 to 40:60.

2. The photosensitive composition according to claim 1,
wherein the pigment A is contained in an amount of 20% to 70% by mass in the total solid content of the photosensitive composition.

3. The photosensitive composition according to claim 1,
wherein the pigment A includes at least one selected from titanium oxide or zirconium oxide.

4. The photosensitive composition according to claim 1,
wherein the photopolymerization initiator D1 is an oxime compound.

5. The photosensitive composition according to claim 1,
wherein the photopolymerization initiator D2 is a compound represented by Formula (V); 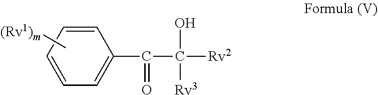
in the formula, Rv¹ represents a substituent, Rv² and Rv³ each independently represent a hydrogen atom or a substituent, Rv² and Rv³ may be bonded to each other to faun a ring, and m represents an integer of 0 to 4.

6. The photosensitive composition according to claim 1,
wherein the photopolymerization initiator D1 and the photopolymerization initiator D2 are contained in a total amount of 4% to 16% by mass in the total solid content of the photosensitive composition.

7. The photosensitive composition according to claim 1,
wherein an acid value of the alkali-soluble resin B is 25 to 200 mgKOH/g.

8. The photosensitive composition according to claim 1,
wherein the alkali-soluble resin B includes a repeating unit having a hydroxyl group.

9. The photosensitive composition according to claim 1,
wherein a hydroxyl number of the alkali-soluble resin B is 30 to 80 mgKOH/g.

10. The photosensitive composition according to claim 1,
which is a composition for forming white pixels in a color filter.

11. A cured film formed by curing the photosensitive composition according to claim 1.

12. A pattern forming method comprising:
forming a photosensitive composition layer on a support using the photosensitive composition according to claim 1;
patternwise exposing the photosensitive composition layer by irradiation with light at a wavelength of more than 350 nm and 380 nm or less;
developing the photosensitive composition layer after the exposure;
exposing the photosensitive composition layer after the development by irradiation with light at a wavelength of 254 to 350 nm.

13. A color filter comprising the cured film according to claim 11.

14. A solid-state imaging element comprising the cured film according to claim 11.

15. An image display device comprising the cured film according to claim 11.
